(19) United States
(12) Patent Application Publication
(10) Pub. No.: US 2018/0066361 A1
(43) Pub. Date: Mar. 8, 2018

(54) THIN FILM MANUFACTURING DEVICE AND THIN FILM MANUFACTURING METHOD

(71) Applicants: NIKON CORPORATION, Tokyo (JP); NATIONAL UNIVERSITY CORPORATION KUMAMOTO UNIVERSITY, Kumamoto (JP)

(72) Inventors: Kei NARA, Yokohama (JP); Makoto NAKAZUMI, Yamato (JP); Yasutaka NISHI, Tokyo (JP); Yusui NAKAMURA, Kumamoto (JP); Takao NAMIHIRA, Kumamoto (JP); Norimitsu TAKAMURA, Fukuoka (JP)

(73) Assignees: NIKON CORPORATION, Tokyo (JP); NATIONAL UNIVERSITY CORPORATION KUMAMOTO UNIVERSITY, Kumamoto (JP)

(21) Appl. No.: 15/680,735

(22) Filed: Aug. 18, 2017

Related U.S. Application Data
(63) Continuation of application No. PCT/JP2016/054607, filed on Feb. 17, 2016.

(30) Foreign Application Priority Data
Feb. 18, 2015 (JP) 2015-030022
Feb. 2, 2016 (JP) 2016-018125

(51) Int. Cl. C23C 16/448; C23C 16/50

(52) U.S. Cl. CPC C23C 16/448; C23C 16/50

(57) ABSTRACT

An object of the invention is to provide a thin film manufacturing device which further reduces a load on a substrate. Provided is a thin film manufacturing device for forming a thin film on a substrate by supplying a mist of a solution including a thin-film forming material to the substrate, characterized in that the device includes: a plasma generation unit including a first electrode and a second electrode disposed closer to one surface of the substrate, which generates plasma between the first electrode and the second electrode; and a mist supply unit which passes the mist between the first electrode and the second electrode and supplies the mist to the substrate.

### CROSS-REFERENCE TO RELATED APPLICATIONS

This application is a continuation application, 35 U.S.C. § 111(a), of International Application No. PCT/JP2016/054607, filed Feb. 17, 2016, and based upon and claiming the foreign priority of Japanese Patent Application No. 2015-030022 filed on Feb. 18, 2015 and Japanese Patent Application No. 2016-018125 filed on Feb. 2, 2016, the contents of which are incorporated by reference herein.

### TECHNICAL FIELD

The present invention relates to a thin film manufacturing device and a thin film manufacturing method.

### BACKGROUND ART

Techniques have been used widely where raw material gases are irradiated with plasma to laminate materials on substrates. Generally, since the lamination step is performed in a vacuum or reduced pressure environment, there is a problem that the device undergoes an increase in size.

Therefore, Patent Literature 1 discloses “a method for continuously treating a sheet-like base material characterized in that: a pair of opposed electrodes is provided in a processing container provided with a sheet introduction port and a sheet discharge port, which is sealed in a non-airtight condition to the extent that gas leakage is acceptable; the opposed surface(s) of one or both of the opposed electrodes are covered with a solid dielectric material; a sheet-like base material is continuously run between the opposed electrodes, and at the same time, a processing gas is continuously brought into contact from the direction opposite to the running direction of the sheet-like base material; and a pulsed electric field is applied between the opposed electrodes to generate discharge plasma”.

### CITATION LIST

### Patent Literature

Patent Literature 1: JP 10-130851 A

### SUMMARY OF INVENTION

### Technical Problem

However, the conventional technique may cause unevenness in the film due to unevenness of the plasma density generated in the electrode planes. In addition, since the base material is disposed between the upper electrode and the lower electrode, there is a possibility that the substrate will be damaged by arc discharge generated partially between the electrodes.

The present invention has been made in view of the foregoing circumstances, and an object of the invention is to provide a thin film manufacturing device which further reduces a load on a substrate.

### Solution to Problem

The present application encompasses multiple means for at least partially solving the problem mentioned above, and will provide an example thereof as follows.

An aspect of the present invention has been achieved in order to solve the problems mentioned above, which is a thin film manufacturing device for forming a thin film on a substrate by supplying a mist of a solution including a thin-film forming material to the substrate, characterized in that the device includes: a plasma generation unit including a first electrode and a second electrode disposed closer to one surface of the substrate, which generates plasma between the first electrode and the second electrode; and a mist supply unit which passes the mist between the first electrode and the second electrode and supplies the mist to the substrate.

In addition, another aspect of the present invention, is a thin film manufacturing method for forming a thin film on a substrate by supplying a mist of a solution including a thin-film forming material to the substrate, characterized in that the method includes: generating plasma between a first electrode and a second electrode disposed closer to one surface of the substrate; and passing the mist between the first electrode and the second electrode and supplying the mist to the substrate.

### BRIEF DESCRIPTION OF DRAWINGS

FIG. 1 is a diagram illustrating an outline of a thin film manufacturing device according to a first embodiment.

FIG. 2(a) and FIG. 2(b) are diagrams (part 1) for explaining details of the thin film manufacturing device according to the first embodiment.

FIG. 3 is a diagram (part 2) for explaining details of the thin film manufacturing device according to the first embodiment.

FIG. 4 is a diagram for explaining details of a thin film manufacturing device according to a second embodiment.

FIG. 5 is a diagram illustrating a configuration example of a thin film manufacturing device according to a third embodiment.

FIG. 6 is a perspective view of a mist ejection unit as viewed from the substrate side.

FIG. 7 is a cross-sectional view of a tip of the mist ejection unit and a pair of electrodes as viewed from the +Y direction.

FIG. 8 is a diagram showing an example of the configuration of a mist generation unit.

FIG. 9 is a block diagram illustrating an example of a schematic configuration of a high-voltage pulse power supply unit 40.

FIG. 10 is a diagram showing an example of waveform characteristics of an inter-electrode voltage obtained in a high-voltage pulse power supply unit configured as shown in FIG. 9.

FIG. 11 is a cross-sectional view illustrating an example of the configuration of the heater unit shown in FIG. 5.

FIG. 12 is a perspective view of a modified example of the mist ejection unit as viewed from the substrate side.

FIG. 13 is a diagram schematically illustrating the overall configuration of a thin film manufacturing device according to a fourth embodiment.

FIG. 14 is a diagram schematically illustrating the overall configuration of a thin film manufacturing device according to a fifth embodiment.

FIG. 15 is a diagram (part 1) illustrating an example of an electrode structure according to a sixth embodiment.

FIG. 16 is a diagram (part 2) illustrating an example of an electrode structure according to the sixth embodiment.

FIG. 17 is a block diagram illustrating an example of the configuration of an electrode structure and a power supply unit that implements a high-voltage pulse voltage application method according to a seventh embodiment.

FIG. 18 is a diagram illustrating a first modified example of the electrode structure provided at the tip of the mist ejection unit.

FIG. 19 is a diagram illustrating a second modified example of the electrode structure provided at the tip of the mist ejection unit.

FIG. 20 is a diagram illustrating a third modified example of the electrode structure provided at the tip of the mist ejection unit.

FIG. 21 is a diagram illustrating a first modified example of the arrangement of mist ejection units.

FIG. 22 is a diagram illustrating a second modified example of the arrangement of mist ejection units.

FIG. 23 is a diagram illustrating a modified example of the tip structure of the mist ejection unit.

FIG. 24 is a diagram showing the result of analysis by XRD for a part just above an electrode in film formation obtained according to Example 1.

FIG. 25 is a diagram showing the result of analysis by XRD for a part away from the part just above the electrode in the film formation obtained according to Example 1.

FIG. 26 is a diagram showing the result of analysis by XRD for a part just above the electrode, of a film obtained according to Comparative Example 1.

FIG. 27 is a diagram showing measurement values of surface roughness for thin films according to Example 2 and Comparative Example 2.

FIG. 28 is an SEM image of the film obtained according to Example 2.

FIG. 29 is an SEM image of the film obtained according to Comparative Example 2.

FIG. 30 is a diagram showing measurement values of surface current for thin films according to Example 2 and Comparative Example 2.

FIG. 31(a) and FIG. 31(b) are diagrams showing the mapping results of surface potentials in Example 2 and Comparative Example 2.

FIG. 32 is a diagram showing the resistivity of a thin film according to Example 3.

### DESCRIPTION OF EMBODIMENTS

An example of an embodiment of the present invention will be described below with reference to the drawings.

### First Embodiment

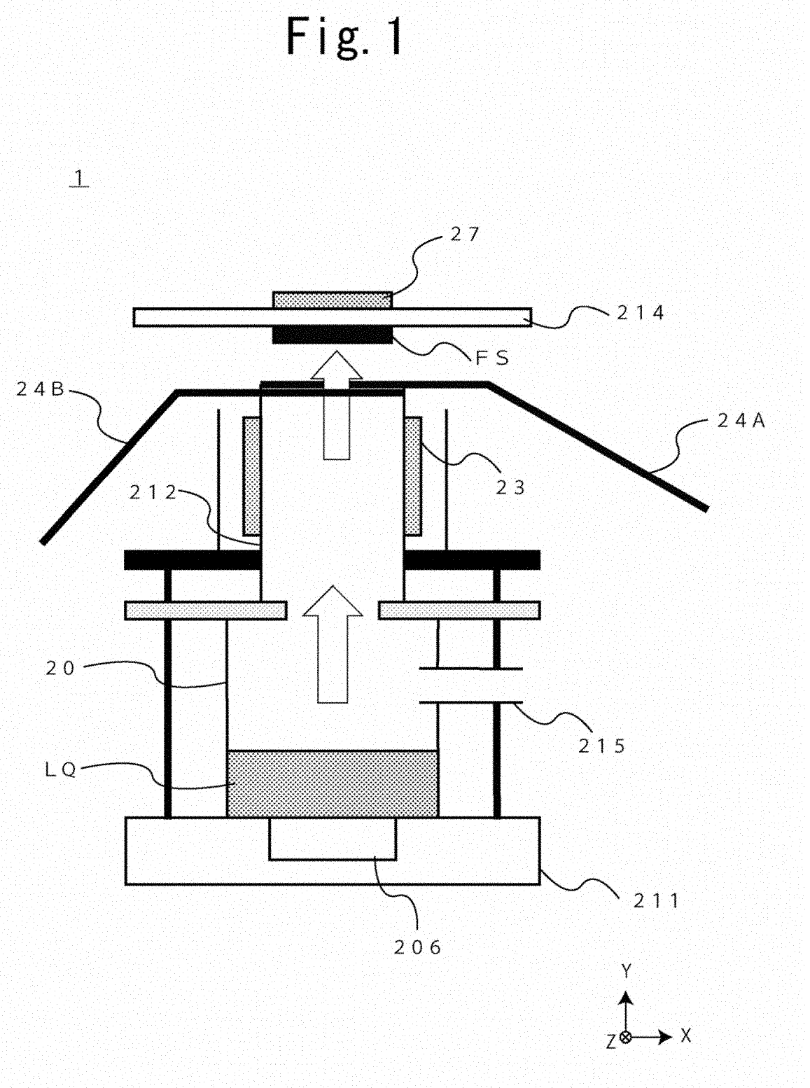

FIG. 1 is a diagram illustrating an outline of a thin film manufacturing device 1 according to a first embodiment. The thin film manufacturing device 1 according to the first embodiment forms a film onto a substrate by a mist CVD (Chemical Vapor Deposition) method. The thin film manufacturing device 1 includes a mist generation tank 20, a heater 23, an electrode 24A, an electrode 24B, a heater unit 27, a gas introduction pipe 215, an ultrasonic transducer 206, a pedestal 211, a mist transport path (mist supply section) 212, and a substrate holder 214. In the mist generation tank 20, a precursor (a solution containing a material for thin film formation) LQ is contained. The substrate holder 214 has a substrate FS placed thereon.

The electrode 24A is a high-voltage electrode, and the electrode 24B is a ground-side electrode. The electrode 24A and the electrode 24B are electrodes of metal conducting wires covered with a dielectric, which will be described in detail later. The electrode 24A and the electrode 24B are placed on the side close to one surface of the substrate FS, and film formation is performed onto the surface. By the application of a voltage to the electrodes, plasma is generated between the electrode 24A and the electrode 24B.

The ultrasonic transducer 206 is a transducer that generates ultrasonic waves, and produces a mist of the precursor LQ in the mist generation tank 20. The pedestal 211 has the transducer embedded therein, and the mist generation tank 20 is placed on the pedestal 211. It is to be noted that the ultrasonic transducer 206 may be placed in the mist generation tank 20. The gas introduction pipe 215 is a pipe that supplies gas to the mist generation tank 20. It is to be noted that the gas introduced into the gas introduction pipe 215 is, for example, Ar or the like, but is not limited thereto. The arrows shown in FIG. 1 indicate the direction of mist flow.

The mist generation tank 20 is a container that contains the precursor LQ. The precursor LQ according to the present embodiment is a solution of a metal salt determined depending on the material to be deposited onto the substrate FS. For example, the solution is an aqueous solution of a metal salt such as a zinc chloride, a zinc acetate, a zinc nitrate, a zinc hydroxide, or an aqueous solution containing a metal complex such as a zinc complex (zinc acetylacetonate). In addition, the solution is not limited to a solution containing zinc, but may be a solution containing a metal salt of any one or more of indium, tin, gallium, titanium, aluminum, iron, cobalt, nickel, copper, silicon, hafnium, tantalum and tungsten, or a metal complex thereof.

The mist transport path 212 is a pipe that guides the mist generated in the mist generation tank 20 to between the electrodes 24A and 24B. The heater 23 is placed on the mist transport path 212, for heating the mist passing through the mist transport path 212. The substrate holder 214 is a pedestal for fixing the substrate FS, and a heater unit 27 for heating the substrate FS may be placed as necessary. In the case of heating the substrate FS, heating is performed at a temperature below the softening point of the substrate FS.

It is to be noted that the softening point herein refers to a temperature at which when the substrate FS is heated, the substrate FS is softened to begin to undergo deformation, which can be obtained, for example, by a test method according to the JIS K 7207 (A method).

For example, a resin film, or foil (foil) made of a metal or an alloy such as stainless steel, or the like is used for the substrate FS. As the material of the resin film, a material may be used which includes one, or two or more resins, for example, among a polyethylene resin, a polypropylene resin, a polyester resin, an ethylene vinyl copolymer resin, a polyvinyl chloride resin, a cellulose resin, a polyamide resin, a polyimide resin, a polycarbonate resin, a polystyrene resin, and a vinyl acetate resin. In addition, the thickness and rigidity (Young's modulus) of the substrate FS have only to fall within such a range as not to cause the substrate FS to have folds or irreversible wrinkles due to buckling when the substrate FS is conveyed. An inexpensive resin sheet such as PET (polyethylene terephthalate) or PEN (polyethylene naphthalate) on the order of 25 μm to 200 μm in thickness is used in the case of creating flexible display panels, touch panels, color filters, electromagnetic wave prevention filters, and the like as electronic devices.

The flow of processing according to the present embodiment will be described. First, in the mist generation tank 20, the precursor LQ therein is made into a mist by the ultrasonic transducer 206. Next, by the gas supplied from the gas introduction pipe 215, the generated mist is supplied to the mist transport path 212. Next, the mist supplied to the mist transport path 212 passes between the electrode 24A and the electrode 24B.

In this regard, the mist is excited by the plasma generated by the application of the voltage to the electrode 24A to act on the surface of the substrate FS on the side where the electrode 24A and the electrode 24B are placed. As a result, a thin film is laminated as a metal oxide to the substrate FS.

It is to be noted that FIG. 1 shows the substrate FS placed horizontally in the thin film manufacturing device 1, and the substrate FS placed so as to be perpendicular to the mist supply direction. However, in the thin film manufacturing device 1, how the substrate FS is placed is not limited thereto. For example, in the thin film manufacturing device 1, the substrate FS may be placed so as to be inclined with respect to the horizontal plane.

Also, in the thin film manufacturing device 1, assuming that the mist transport path 212 has a plane perpendicular to the direction in which the mist is supplied to the substrate FS, the substrate FS may be placed so as to be inclined with respect to the plane. The inclination direction is also not limited.

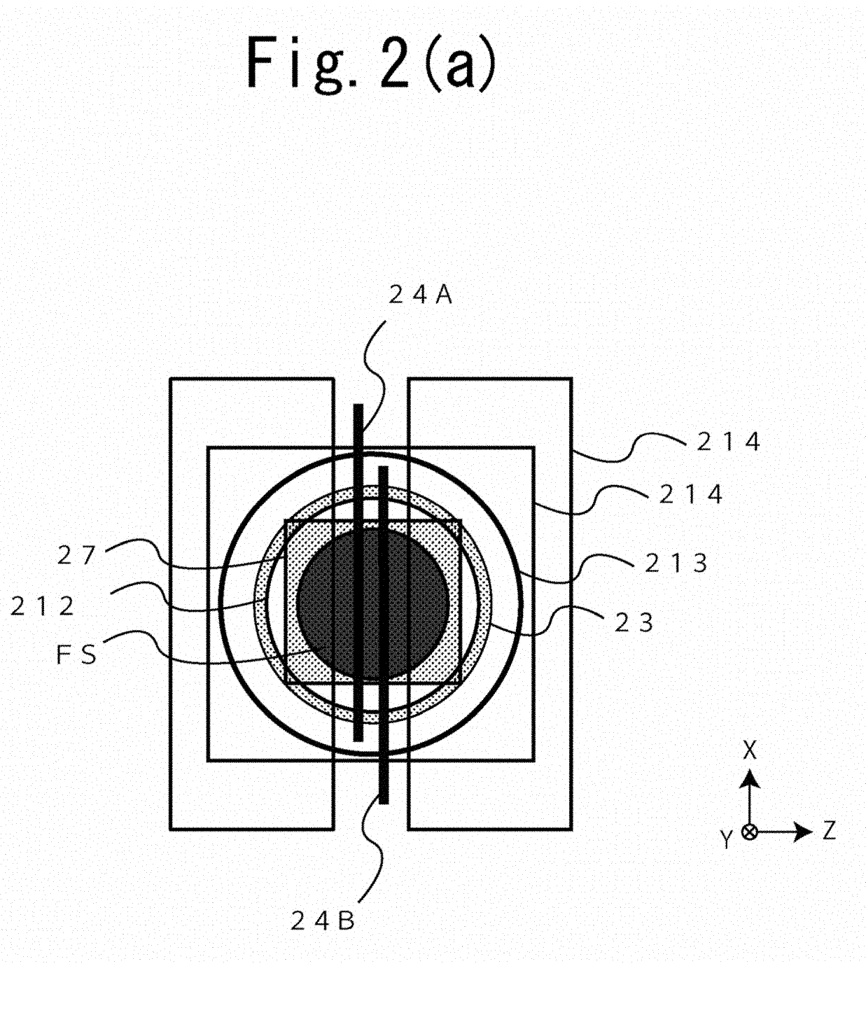

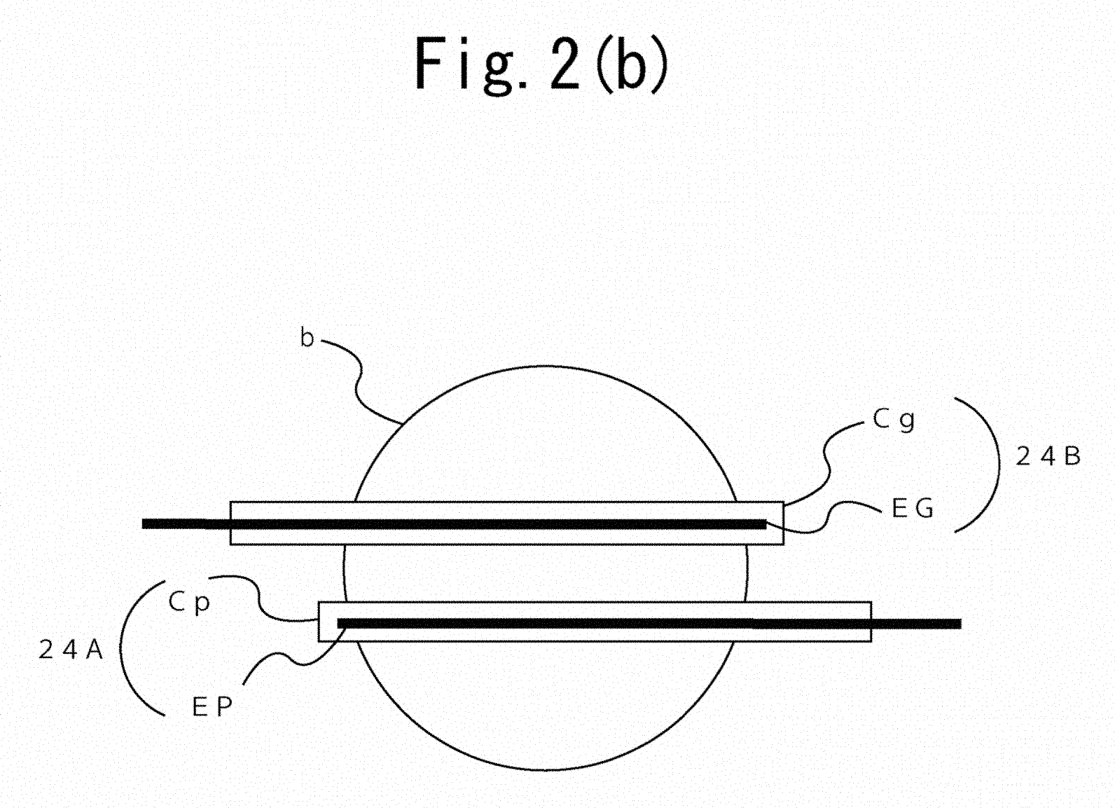

FIG. 2(a) and FIG. 2(b) are diagrams (part 1) for explaining details of the thin film manufacturing device 1 according to the first embodiment. FIG. 2(a) shows the thin film manufacturing device 1 as viewed from above, that is, the thin film manufacturing device 1 in FIG. 1 as looked down from the +Y direction. It is the thin film manufacturing device 1 shown in FIG. 1 that corresponds to a sectional view of the thin film manufacturing device 1 shown in FIG. 2(a) as cut along a plane parallel to the X-axis direction and viewed from the +Z direction. For the sake of explanation, each constituent element is illustrated as being transparent, but how the actual constituent element is transparent is not limited to the embodiment shown in this drawing. Further, in FIG. 2(a), the outer diameter 213 of the mist transport path 212 is shown.

According to the present embodiment, the mist transport path 212 which has a substantially ring shape is heated by the heater 23, and the mist in the heated mist transport path 212 passes between the electrodes 24A and 24B, and acts on the substrate FS.

FIG. 2(b) shows the thin film manufacturing device 1 shown in FIG. 2(a) as rotated clockwise by 90 degrees and looked up from the downward direction (−Y direction shown in FIG. 1).

The electrode 24A includes a wire-shaped electrode EP and a dielectric Cp. The electrode 24B includes an electrode EG and a dielectric Cg. The materials of the electrode EP and electrode EG are not limited as long as the materials are conductors, but, for example, tungsten, titanium, and the like can be used.

It is to be noted that the electrode EP and the electrode EG are not limited to wires, but may be flat plates, and in the case of the electrodes composed of flat plates, the surfaces formed by the opposed edge portions are desirably parallel. Although the electrodes may be composed of flat plates with sharp edges like a knife, there is a possibility that an electric field will be concentrated on edge ends, thereby causing arcing. It is to be noted that that the electrodes desirably have a wire shape rather than a flat-plate shape, because the smaller the surface area of the electrode is, the higher the plasma generation efficiency is.

In addition, the electrode EP and the electrode EG will be described as straight lines, but may be each bent.

A dielectric is used for the dielectric Cp and the dielectric Cg. For the dielectric Cp and the dielectric Cg, for example, quartz and ceramics (insulating material such as silicon nitride, zirconia, alumina, silicon carbide, aluminum nitride, and magnesium oxide) can be used.

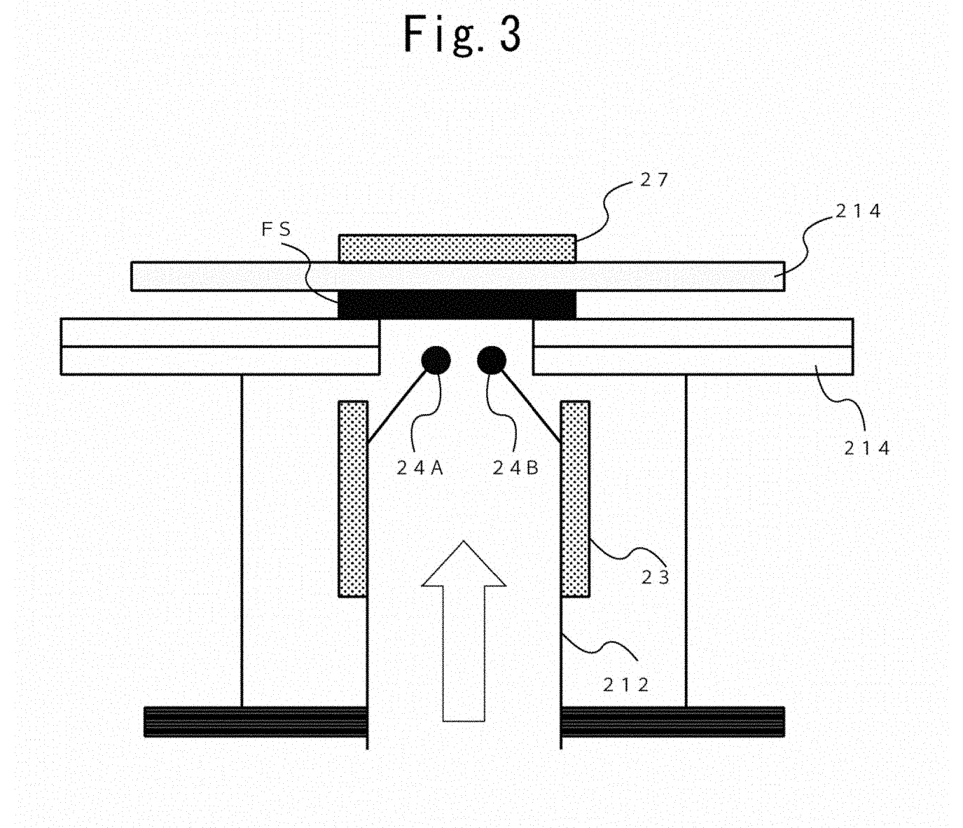

According to the present embodiment, plasma is generated by dielectric barrier discharge. To that end, it is necessary to place a dielectric between the electrode EP and the electrode EG. The relative positional relationship between the metal conducting wires and the dielectric is not limited to the example shown in FIG. 3, but for example, one of the electrode EP and the electrode EG may be covered with a dielectric. Further, as shown in FIG. 3, it is more desirable to cover both the electrode EP and the electrode EG with a dielectric. This is because degradation due to adhesion of the mist to the metal conducting wires can be prevented. It is to be noted that that the electrodes EP and EG are desirably arranged substantially in parallel such that plasma can be generated stably.

FIG. 3 is a diagram (part 2) for explaining details of the thin film manufacturing device 1 according to the first embodiment. FIG. 3 shows an upper portion from the mist transport path 212 of the thin film manufacturing device 1 where the thin film manufacturing device 1 shown in FIG. 2(a) is cut along a plane parallel to the Z-axis direction and viewed from the −X direction.

The mist introduced from the mist generation tank 20 is heated in the mist transport path 212. Thereafter, the mist reaches the electrode 24A and the electrode 24B. The mist is excited by the plasma generated between the respective electrodes, and adheres to the substrate FS, thereby forming a thin film.

In the thin film manufacturing device 1 according to the first embodiment, the electrode 24A and the electrode 24B for generating plasma are positioned on the side closer to one surface of the substrate FS. Therefore, damage to the substrate FS due to arc discharge or the like can be further reduced.

It is to be noted that the thin film manufacturing device 1 according to the first embodiment can produce a thin film onto the substrate FS even in a non-vacuum state. Therefore, unlike a sputtering method or the like, it is possible to prevent an increase in device size and an increase in cost, thereby reducing the load on the environment. In addition, unlike a so-called thermal CVD method for the formation of a thin film through the use of a chemical reaction by thermal decomposition, low-temperature formation is possible. Thus, the heat load on the substrate FS is reduced.

### Second Embodiment

Next, a second embodiment will be described. According to the second embodiment, film formation is performed onto a substrate FS by using a mist deposition method. Hereinafter, differences from the first embodiment will be described, and duplicate descriptions will be omitted.

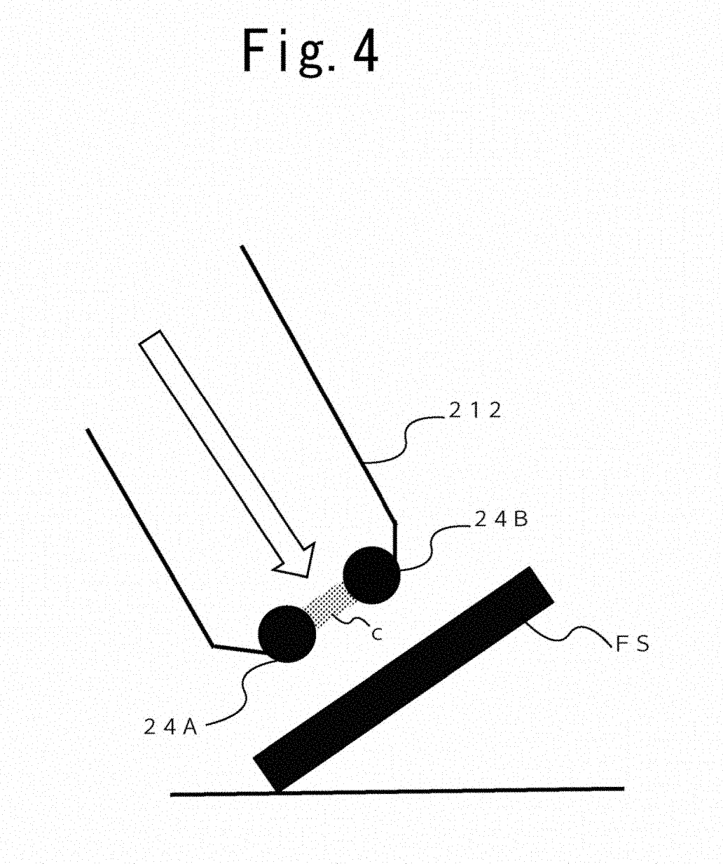

FIG. 4 is a diagram for explaining details of a thin film manufacturing device 1 according to the second embodiment. In a mist generation tank 20 according to the present embodiment, a dispersion liquid in which metal oxide fine particles are dispersed in a dispersion medium is stored as a precursor LQ. For the fine particles, metal fine particles that have conductivity, such as indium, zinc, tin or titanium, and metal oxide fine particles containing at least one of the metal fine particles can be used. These fine particles maybe used singly, or two or more thereof may be combined arbitrarily. The fine particles are nanoparticles of 1 to 100 nm in particle size. It is to be noted that explanations will be made, provided that metal oxide fine particles are used as fine particles according to the present embodiment. The dispersion medium has only to be capable of dispersing the fine particles, and water, an alcohol such as isopropyl alcohol (IPA) and ethanol, or a mixture thereof can be used for the dispersion medium.

The mist transport path 212 guides the mist introduced from the mist generation tank 20 to between the electrode 24A and the electrode 24B. The mist affected by plasma c generated between the electrodes is sprayed onto the substrate FS for a predetermined period of time. Then, through vaporization of the dispersion medium of the mist attached to the substrate FS, a metal oxide film is formed on the surface of the substrate FS.

In this regard, a substrate holder 214, not shown, may have the substrate FS placed in the thin film manufacturing device 1 such that the substrate FS is inclined with respect to the horizontal plane. While a mist adheres to the substrate FS and vaporizes to form a thin film onto the substrate FS, tilting the substrate FS with respect to the horizontal plane can keep a dropletized mist that has adhered onto the thin film from flowing down, thereby resulting in nonuniform formation of a thin film.

It is to be noted that the substrate holder 214 may be placed in the thin film manufacturing device 1, in a way that the mist transport path 212 is inclined with respect to a plane perpendicular to the direction in which a mist is sprayed to the substrate FS. Thus, for example, when patterning is performed by providing the substrate FS with a water-repellent part in advance, a mist that adheres to the water-repellent part can be removed with the momentum of spraying.

### Third Embodiment

Next, a third embodiment will be described. Hereinafter, differences from the embodiments described above will be described, and duplicate descriptions will be omitted. It is to be noted that a mist generation unit 20A, a mist generation unit 20B, a duct 21A, and a duct 21B according to the present embodiment correspond to the mist generation tank 20 of the thin film manufacturing device 1 according to the embodiments described above, and a mist ejection unit 22 corresponds to the mist transport path 212.

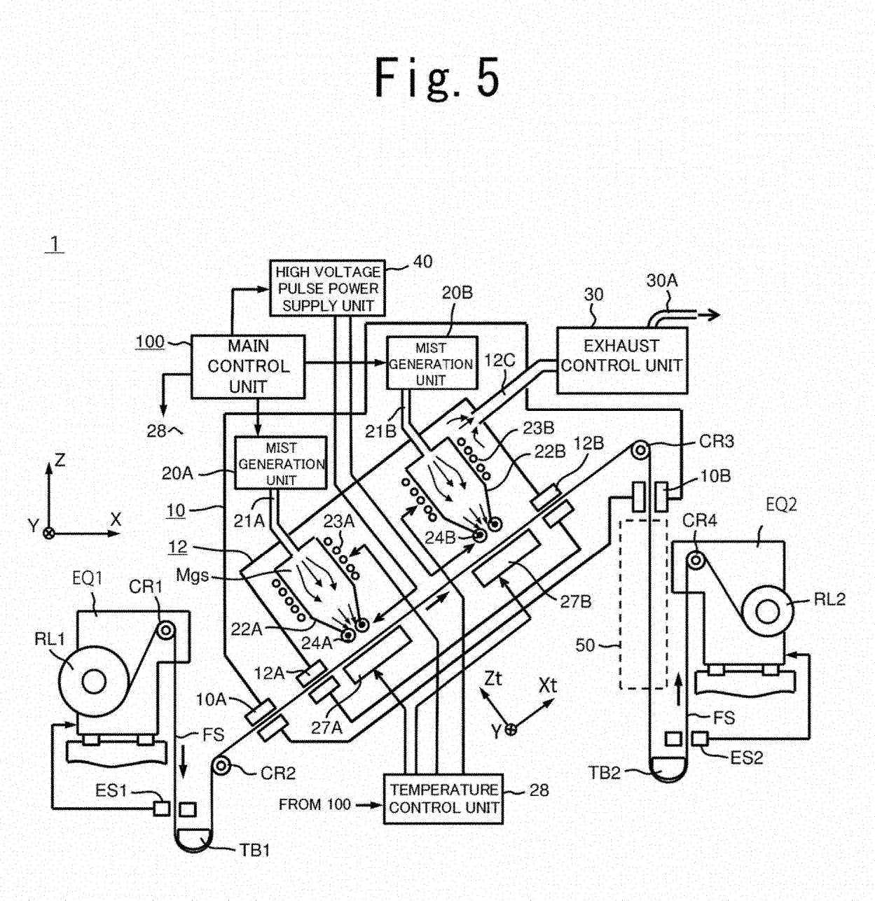

FIG. 5 is a diagram illustrating a configuration example of a thin film manufacturing device 1 according to the third embodiment. The thin film manufacturing device 1 according to the present embodiment continuously produces a thin film of a specific substance such as a metal oxide on the surface of a flexible long sheet substrate FS by a roll-to-roll (Roll to Roll) method.

[Schematic Configuration of Device]

In FIG. 5, an orthogonal coordinate system XYZ is defined so that the floor surface of a factory where the device main body is installed is regarded as an XY plane, whereas the direction perpendicular to the floor surface is regarded as a Z direction. In addition, in the thin film manufacturing device 1 of FIG. 5, the surface of the sheet substrate FS always perpendicular to the XZ plane is supposed to be conveyed in the longitudinal direction.

The long sheet substrate FS (hereinafter, also referred to simply as a substrate FS) as an object to be processed is wound around a supply roll RL1 attached to a mount EQ1 over a predetermined length. The mount EQ1 is provided with a roller CR1 for hanging the sheet substrate FS drawn out from the supply roll RL1, and the rotation center axis of the supply roll RL1 and the rotation center axis of the roller CR1 extend in the Y direction (the direction perpendicular to the paper surface of FIG. 5) so as to be parallel to each other. The substrate FS bent in the −Z direction (gravitational direction) by the roller CR1 is folded back in the +Z direction by an air turn bar TB1, and is bent obliquely upward (in the range of 45°±15° with respect to the XY plane) by a roller CR2. The air turn bar TB1 is, for example, as described in WO2013/105317, intended to turn the conveying direction, with direction the substrate FS slightly floated by an air bearing (gas layer). It is to be noted that the air turn bar TB1 is movable in the Z direction by driving a pressure regulation unit, not shown, and applies tension to the substrate FS in a non-contact manner.

The substrate FS passing through the roller CR2 is passed through a slit-like air-sealing part 10A of a first chamber 10, and then passed through a slit-like air-sealing part 12A of a second chamber 12 that houses a film formation main body, and carried linearly in an obliquely upward direction into the second chamber 12 (film formation main body). When the substrate FS is fed at a constant speed in the second chamber 12, a film of a specific substance with a predetermined thickness is produced on the surface of the substrate FS by a mist deposition method assisted by atmospheric pressure plasma or a mist CVD method.

The substrate FS subjected to film formation processing in the second chamber 12 is discharged from the second chamber 12 through a slit-like air-sealing part 12B, then bent in the −Z direction by a roller CR3, and discharged from the first chamber 10 through a slit-like air-sealing part 10B. The substrate FS moved in the −Z direction from the air-sealing part 10B is folded back in the +Z direction by an air turn bar TB2, then bent by a roller CR4 provided on a mount EQ2, and wound up by a collection roll RL2. The collection roll RL2 and the roller CR4 are provided on the mount EQ2 to extend in the Y direction (the direction perpendicular to the paper surface of FIG. 5) such that their rotation center axes are parallel to each other. Further, if necessary, a drying unit (heating unit) 50 for drying unnecessary water components attached to the substrate FS or with which the substrate FS impregnated may be provided in the conveying path from the air-sealing part 10B to the air turn bar TB2.

The air-sealing parts 10A, 10B, 12A, and 12B shown in FIG. 5 are, as disclosed in WO2012/115143, provided with slit-like apertures that carries in and out the sheet substrate FS in the longitudinal direction, while blocking the flow of gas (atmospheric air, etc.) between spaces inside and outside the partition wall of the first chamber 10 or the second chamber 12. Air bearings (static pressure gas layers) of vacuum pressurized method are formed between the upper edge sides of the apertures and the upper surface (surface to be processed) of the sheet substrate FS, and between the lower edge sides of the apertures and the lower surface (back surface) of the sheet substrate FS. Therefore, the mist gas for film formation remains in the second chamber 12 and in the first chamber 10, such that the gas is prevented from leaking to the outside.

In the case of the present embodiment herein, the conveyance control and the tension control in the longitudinal direction of the substrate FS are achieved by a servomotor provided on the mount EQ2 so as to rotationally drive the collection roll RL2, and a servomotor provided on the mount EQ1 so as to rotationally drive the supply roll RL1. Although not shown in FIG. 5, the respective servomotors provided on the mount EQ2 and the mount EQ1 are controlled by a motor control unit, such that predetermined tension (longitudinal direction) is provided to the substrate FS at least between the roller CR2 and the roller CR3 while setting the conveyance speed of the substrate FS as a target value. The tension of the seat substrate FS can be obtained by providing a load cell or the like for measuring a force that pushes up the air turn bar TB1, TB2 in the +Z direction, for example.

Further, the mount EQ1 (and the supply roll RL1, the roller CR1) have the function of slightly moving in the range on the order of ±several mm in the Y direction by a servomotor or the like, in accordance with detection results from an edge sensor ES1 that measures variations in the Y direction (the width direction perpendicular to the longitudinal direction of the sheet substrate FS) in edge (end) positions on both sides of the sheet substrate FS immediately before reaching the air turn bar TB1, that is, the EPC (edge position control) function. Thus, even when the sheet substrate rolled up around the supply roll RL1 has uneven winding in the Y direction, the center position in the Y direction of the sheet substrate passing the roller CR2 always has a variation reduced within a certain range (e.g., ±0.5 mm). Therefore, the sheet substrate accurately positioned with respect to the width direction is carried into the film formation main body (second chamber 12).

Likewise, the mount EQ2 (and the collection roll RL2, the roller CR4) have the EPC function of slightly moving in the range on the order of ±several mm in the Y direction by a servomotor or the like, in accordance with detection results from an edge sensor ES2 that measures variations in the Y direction in edge (end) positions on both sides of the sheet substrate FS immediately after passing the air turn bar TB2. Thus, the sheet substrate FS subjected to film formation is rolled up around the collection roll RL2, while being prevented from undergoing uneven winding in the Y direction. Further, the mounts EQ1 and EQ2, the supply roll RL1, the collection roll RL2, the air turn bars TB1 and TB2, and the rollers CR1, CR2, CR3 and CR4 have a function as a conveying unit for guiding the substrate FS to the mist ejection unit 22.

In the device of FIG. 5, the rollers CR2 and CR3 are arranged such that the linear conveying path of the sheet substrate FS in the film forming main body (the second chamber 12) is inclined and thus increased by on the order of 45°±15° (here, 45°) in the conveying direction of the substrate FS. Due to this inclination of the conveying path, mists (liquid particles including particles or molecules of a specific substance) sprayed onto the sheet substrate FS by a mist deposition method or a mist CVD method can be retained to a moderate degree on the surface of the sheet substrate FS, thereby improving the deposition efficiency (also referred to as film formation rate or film formation speed) of the specific substance. While the configuration of the film formation main body will be described later, the substrate FS is inclined in the longitudinal direction in the second chamber 12, the orthogonal coordinate system Xt·Y·Zt is thus set with a plane parallel to the surface to be processed of the substrate FS as a Y·Xt plane, and with a direction perpendicular to the Y·Xt plane as Zt.

According to the present embodiment, two mist ejection units 22A, 22B are provided in the second chamber 12 at a regular interval in the conveying direction (Xt direction) of the substrate FS. The mist ejection units 22A and 22B are formed in a cylindrical shape, and on the tip sides opposed the substrate FS, slot (slit)-like apertures elongated in the Y direction are provided for ejecting a mist gas (a mixed gas of a carrier gas and a mist) Mgs toward the substrate FS. Furthermore, a pair of parallel electrodes 24A and 24B for generating atmospheric pressure plasma in a non-thermal equilibrium state is provided near the apertures of the mist ejection units 22A and 22B. A pulse voltage from the high-voltage pulse power supply unit 40 is applied to the pair of electrodes 24A, 24B each at a predetermined frequency. In addition, heaters (temperature regulators) 23A, 23B for maintaining the internal spaces of the mist ejection units 22A, 22B at a set temperature are provided on the outer periphery of the mist ejection units 22A, 22B. The heaters 23A and 23B are controlled by a temperature control unit 28 so as to reach a set temperature.

The mist gas Mgs generated in the first mist generation unit 20A and the second mist generation unit 20B is supplied at a predetermined flow rate to each of the mist ejection units 22A and 22B via the ducts 21A and 21B. The mist gas Mgs ejected from the slot-like apertures of the mist ejection units 22A, 22B in the −Zt direction is blown onto the upper surface of the substrate FS at a predetermined flow rate, and thus allowed to flow immediately downward (−Z direction) as it is. In order to extend the residence time of the mist gas on the upper surface of the substrate FS, the gas in the second chamber 12 is suctioned by an exhaust control unit 30 via a duct 12C. More specifically, the creation of a flow of gas from the slot-like apertures of the mist ejection units 22A, 22B toward the duct 12C in the second chamber 12 prevents the mist gas Mgs from flowing from the upper surface of the substrate FS immediately downward (−Z direction).

The exhaust control unit 30 removes particulates and molecules of a specific substance, or a carrier gas, included in the suctioned gas in the second chamber 12, to produce a clean gas (air), and then discharges the gas into the environment via a duct 30A. It is to be noted that while the mist generation units 20A, 20B are provided outside the second chamber 12 (inside the first chamber 10) in FIG. 5, for reducing the volume of the second chamber 12, thereby making it easier to control the flow of gas (flow rate, flow speed, flow path, etc.) in the second chamber 12 when the gas is suctioned by the exhaust control unit 30. Of course, the mist generation units 20A and 20B may be provided inside the second chamber 12.

In the case of depositing a film on the substrate FS by a mist CVD method with the use of the mist gas Mgs from each of the mist ejection units 22A and 22B, it is necessary to set the substrate FS at a temperature higher than normal temperature, for example, about 200° C. Therefore, according to the present embodiment, heater units 27A and 27B are provided in positions (the back side of the substrate FS) opposed to the respective slot-like apertures of the mist ejection units 22A, 22B with the substrate FS therebetween, and controlled by the temperature control unit 28 such that the temperature of a region on the substrate FS where the mist gas Mgs is ejected reaches the set value. On the other hand, in the case of film formation by a mist deposition method, it is not necessary to operate the heater units 27A, 27B because normal temperature may be adopted, but when it is desirable to set the substrate FS to a temperature higher than normal temperature (for example, 90° C. or lower), the heater units 27A and 27B can be operated as appropriate.

The mist generation units 20A, 20B, the temperature control unit 28, the exhaust control unit 30, the high-voltage pulse power supply unit 40, and the motor control unit (the control system for the servomotors that rotationally drive the supply roll RL1 and the collection roll RL2), and the like are controlled by a main control unit 100 including a computer in an integrated manner.

[Sheet Substrate]

Next, the sheet substrate FS as an object to be processed will be described. As described above, for example, a resin film, or foil (foil) made of a metal or an alloy such as stainless steel, or the like is used for the substrate FS. As the material of the resin film, a material may be used which includes one, or two or more resins, for example, among a polyethylene resin, a polypropylene resin, a polyester resin, an ethylene vinyl copolymer resin, a polyvinyl chloride resin, a cellulose resin, a polyamide resin, a polyimide resin, a polycarbonate resin, a polystyrene resin, and a vinyl acetate resin. In addition, the thickness and rigidity (Young's modulus) of the substrate FS have only to fall within such a range as not to cause the substrate FS to have folds or irreversible wrinkles due to buckling when the substrate FS is conveyed. An inexpensive resin sheet such as PET (polyethylene terephthalate) or PEN (polyethylene naphthalate) on the order of 25 μm to 200 μm in thickness is used in the case of creating flexible display panels, touch panels, color filters, electromagnetic wave prevention filters, and the like as electronic devices.

For example, the substrate FS which is not significantly large in coefficient of thermal expansion is desirably selected so as to achieve a substantially negligible amount of deformation due to heat applied in various types of processing applied to the substrate FS. In addition, when an inorganic filler such as titanium oxide, zinc oxide, alumina, or silicon oxide, for example, is mixed with the resin film as a base, the coefficient of thermal expansion can be reduced. Further, the substrate FS may be a single-layer body of ultrathin glass on the order of 100 μm in thickness manufactured by a float method or the like, or a single-layer body of a metal sheet obtained by rolling a metal such as stainless steel into a thin film shape, or may be a laminated body obtained by attaching the resin film mentioned above, a metal layer (foil) such as aluminum or copper, or the like to the ultrathin glass or the metal sheet. Furthermore, in the case of film formation by a mist deposition method with the use of the thin film manufacturing device 1 according to the present embodiment, the temperature of the substrate FS can be set to 100° C. or lower (typically on the order of normal temperature), but in the case of film formation by the mist CVD method, it is necessary to set the temperature of the substrate FS to on the order of 100° C. to 200° C. Therefore, in the case of film formation by a mist CVD method, a substrate material (for example, polyimide resin, ultrathin glass, metal sheet, etc.) is used which undergoes no deformation or alteration even at a temperature on the order of 200° C.

Now, the flexibility (flexibility) of the substrate FS refers to the property that it is possible to make the substrate FS flexible without any disconnection or fracture, even when the substrate FS has a force on the order of its own weight applied thereto. In addition, the flexibility also encompasses the property of being flexed by the force on the order of its own weight. In addition, the degree of flexibility varies depending on the material, size, and thickness of the substrate FS, the layer structure formed on the substrate FS, environments such as temperature and humidity, and the like. In any case, as long as the substrate FS can be conveyed smoothly without any buckling resulting in the formation of folds or breakage (generation of tears or cracks) when the substrate FS is wound correctly around various types of conveying rollers, turn bars, rotating drums, etc. provided in the conveying path of the thin film manufacturing device 1 according to the present embodiment or a manufacturing device that controls processes before and after the thin film manufacturing device 1, it can be said to fall within the scope of flexibility.

It is to be noted that the substrate FS supplied from the supply roll RL1 shown in FIG. 5 may be a substrate in intermediate process. More specifically, a specific layer structure for electronic devices may be formed already on the surface of the substrate FS rolled up around the supply roll RL1. The layer structure refers to a single layer such as a resin film (insulating film) or a metal thin film (copper, aluminum, etc.) formed to have a certain thickness on the surface of the sheet substrate as a base, or a multilayer structure of the films thereon. Further, as disclosed in, for example, WO2013/176222, the substrate FS to which a mist deposition method is applied in the thin film manufacturing device 1 in FIG. 5 may have a surface condition provided with a large difference in lyophilic/lyophobic property with respect to the mist solution between parts irradiated or non-irradiated with ultraviolet light, by applying a photosensitive silane coupling material on the surface of the substrate, drying the material, and then irradiating the material with ultraviolet light (with a wavelength of 365 nm or less) in accordance with a distribution corresponding to the shape of a pattern for electronic devices through the use of an exposure device. In this case, the mist can be attached selectively to the surface of the substrate FS in accordance with the shape of the pattern by a mist deposition method with the use of the thin film manufacturing device 1 of FIG. 1.

Furthermore, the long sheet substrate FS supplied to the thin film manufacturing device 1 of FIG. 5 may have a resin sheet or the like of a standard size corresponding to the size of an electronic device to be manufactured, attached to the surface of a long thin metal sheet (for example, a SUS belt on the order of 0.1 mm in thickness) at a regular interval in the longitudinal direction of the metal sheet. In this case, the object to be processed, subjected to film formation by the thin film manufacturing device 1 of FIG. 5 is a resin sheet that has a standard size.

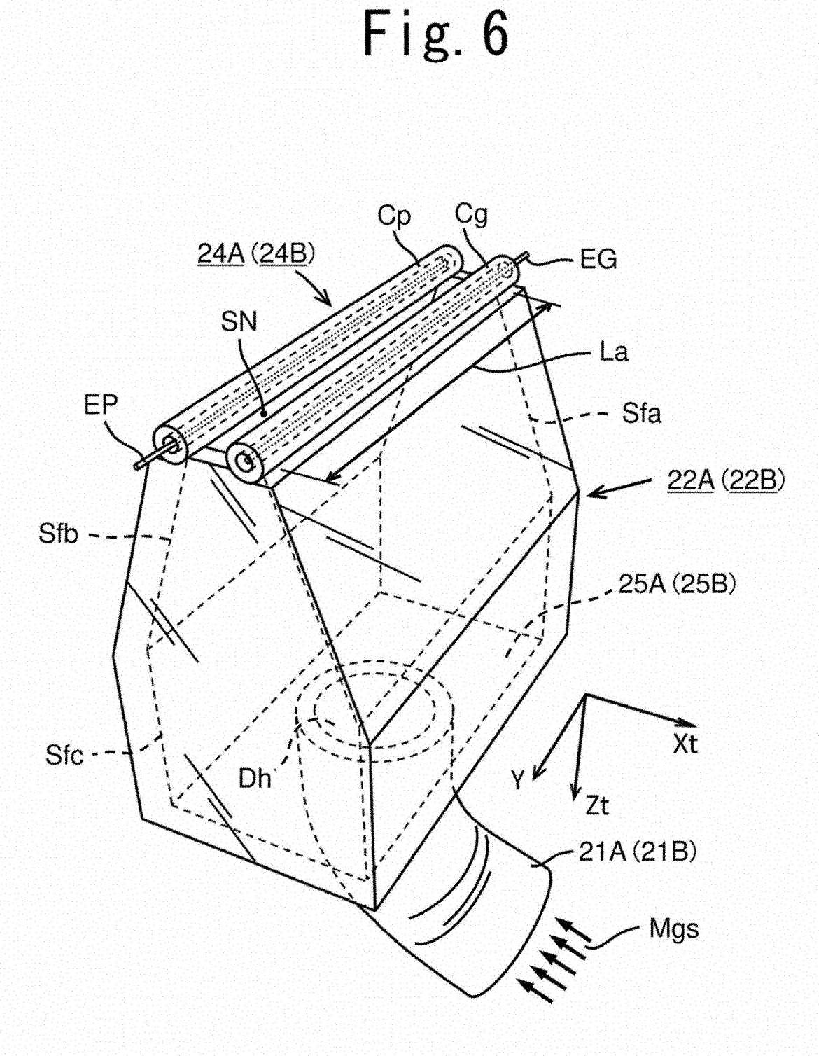

Next, the configurations of respective units in the thin film manufacturing device 1 in FIG. 5 will be described with reference to FIGS. 6 to 9 along with FIG. 5.

[Mist Ejection Units 22A, 22B]

FIG. 6 is a perspective view of the mist ejection unit 22A (as well as 22B) as viewed from the −Zt side of the coordinate system Xt·Y·Zt, that is, from the substrate FS side. The mist ejection unit 22A is composed of a quartz plate, which has inclined inner walls Sfa, Sfb with a fixed length in the Y direction, and with a width in the Xt direction gradually decreased in the −Zt direction, inner walls Sfc of side surfaces parallel to the Xt·Zt surface, and a top board 25A (25B) parallel to the Y·Xt surface. The duct 21A (21B) from the mist generation unit 20A (20B) is connected to an opening Dh in the top board 25A (25B), and the mist gas Mgs is supplied into the mist ejection unit 22A (22B). The mist ejection unit 22A (22B) has, at the tip thereof in the −Zt direction, a slot-like aperture SN formed, which is elongated in the Y direction over a length La, and the pair of electrodes 24A (24B) is provided so as to sandwich the aperture SN in the Xt direction. Therefore, the mist gas Mgs (positive pressure) supplied into the mist ejection unit 22A (22B) through the opening Dh is passed through the space between the pair of electrodes 24A (24B) from the slot-like aperture SN, and ejected with a uniform flow rate distribution in the −Zt direction.

The pair of electrodes 24A is composed of a wire-like electrode EP extending in the Y direction in excess of a length La, and a wire-like electrode EG extending in the Y direction in excess of the length La. The electrodes EP and EG are respectively held in a cylindrical quartz tube Cp1 that functions as a dielectric Cp and a quartz tube Cg1 that functions as a dielectric Cg so as to be parallel at a predetermined interval in the Xt direction, and fixed to the tips of the mist ejection unit 22A (22B) so that the quartz tubes Cp1, Cg1 are located on both sides of the slot-like aperture SN. The quartz tubes Cp1 and Cg1 desirably contain therein no metal component. In addition, the dielectrics Cp and Cg may be tubes made of ceramics that are high in dielectric strength voltage.

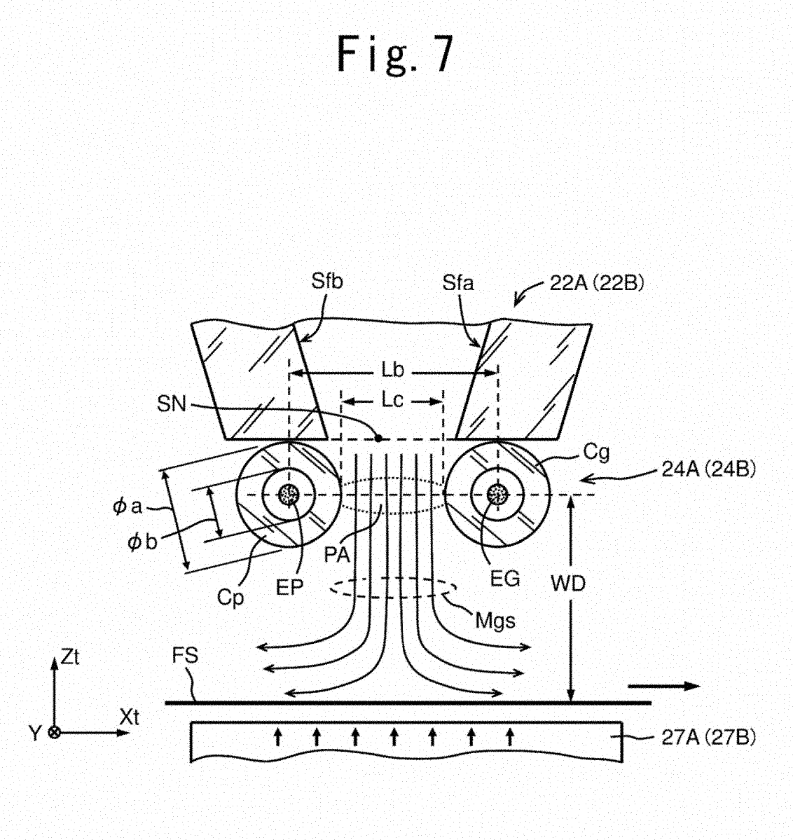

FIG. 7 is a cross-sectional view of a tip of the mist ejection unit 22A (22B) and the pair of electrodes 24A (24B) as viewed from the +Y direction. According to the present embodiment, as an example, the outer diameter φa of the quartz tubes Cp1, Cg1 is set to about 3 mm, whereas the inner diameter φb thereof is set to about 1.6 mm (wall thickness: 0.7 mm), and the electrodes EP, EG are composed of wires of 0.5 to 1 mm in diameter, made from low-resistance metal such as tungsten or titanium. The electrodes EP and EG are held by insulators at both ends of the quartz tubes Cp1, Cg1 in the Y direction so as to pass linearly through the centers of the inner diameters of the quartz tubes Cp1, Cg1. It is to be noted that there has only to be anyone of the quartz tubes Cp1, Cg1, and for example, the electrode EP connected to a positive electrode of the high-voltage pulse power supply unit 40 may be surrounded by the quartz tube Cp1, whereas the electrode EG connected to a negative electrode (ground) of the high-voltage pulse power supply unit 40 may be exposed. However, because the exposed electrode EG is contaminated or corroded depending on the gas component of the mist gas Mgs ejected from the aperture SN at the tip of the mist ejection unit 22A (22B), the electrodes EP, EG are preferably both surrounded by the quartz tube Cp1, Cg1, that is, configured such that the mist gas Mgs are not brought into direct contact with the electrodes EP, EG.

In this regard, each of the wire-like electrodes EP and EG is disposed in parallel to the surface of the substrate FS in a position at a height of working distance (working distance) WD from the surface of the substrate FS, and disposed at an interval Lb in the conveying direction (+Xt direction) of the substrate FS. The interval Lb is set to be as narrow as possible in order to generate atmospheric pressure plasma in a non-thermal equilibrium state continuously in a stable manner in a uniform distribution in the −Zt direction, and set to on the order of 5 mm as an example. Therefore, the effective width (gap) Lc in the Xt direction is Lc=Lb−φa when the mist gas Mgs injected from the aperture SN of the mist ejection unit 22A (22B) passes between the pair of electrodes, and when a quartz tube of 3 mm in outer diameter is used, the width Lc is about 2 mm.

Furthermore, although not essential, it is preferable to make the working distance WD larger as compared with the interval Lb in the Xt direction between the wire-like electrodes EP, EG. This is because if there is an arrangement relationship of Lb>WD, there is a possibility that plasma will be generated between the electrode EP (quartz tube Cp1) which serves as a positive electrode and the substrate FS, or arc discharge will be caused therebetween.

In other words, the working distance WD, which is the distance from the electrodes EP, EG to the substrate FS, is desirably longer than the distance Lb between the electrodes EP, EG.

However, when the potential of the substrate FS can be set between the potential of the electrode EG which serves as a grounding electrode and the potential of the electrode EP which serves as a positive electrode, it is also possible to set Lb>WD.

It is to be noted that there is no need for the plane formed by the electrode 24A and the electrode 24B to be parallel to the substrate FS. In that case, the distance from a part of the electrodes closest to the substrate FS to the substrate FS is regarded as the interval WD, and the installation position of the mist ejection unit 22A (22B) or the substrate FS is adjusted.

In the case of the present embodiment, the plasma in the non-thermal equilibrium state is strongly generated in a region with the narrowest interval between the pair of electrodes 24A (24B), that is, in a limited region PA in the Zt direction with the width Lc in FIG. 7. Therefore, reducing the working distance WD comes to be able to shorten the time from when the mist gas Mgs is irradiated with the plasma in the non-thermal equilibrium state until when the mist gas Mgs reaches the surface of the substrate FS, and the film formation rate (deposition film thickness per unit time) can be expected to be improved. In FIG. 7, when the interval Lb in the Xt direction between the wire-like electrodes EP, EG is 5 mm, the working distance WD can be set to about 5 mm.

When the distance Lb (or width Lc) between the pair of electrodes 24A (24B) and the working distance WD are not changed, the film formation rate is changed by the peak value and frequency of the pulse voltage applied between the electrodes EP, EG, the flow rate (speed) of the mist gas Mgs ejected from the aperture SN, the concentrations of specific substances (fine particles, molecules, ions, etc.) for film formation, included in the mist gas Mgs, or the heating temperature of the heater unit 27A (27B) placed on the back side of the substrate FS, etc., and these conditions are thus adjusted appropriately by the main control unit 100, depending on the type of a specific substance to be deposited on the substrate FS, the thickness of the film formation, the flatness, etc.

[Mist Generation Units 20A, 20B]

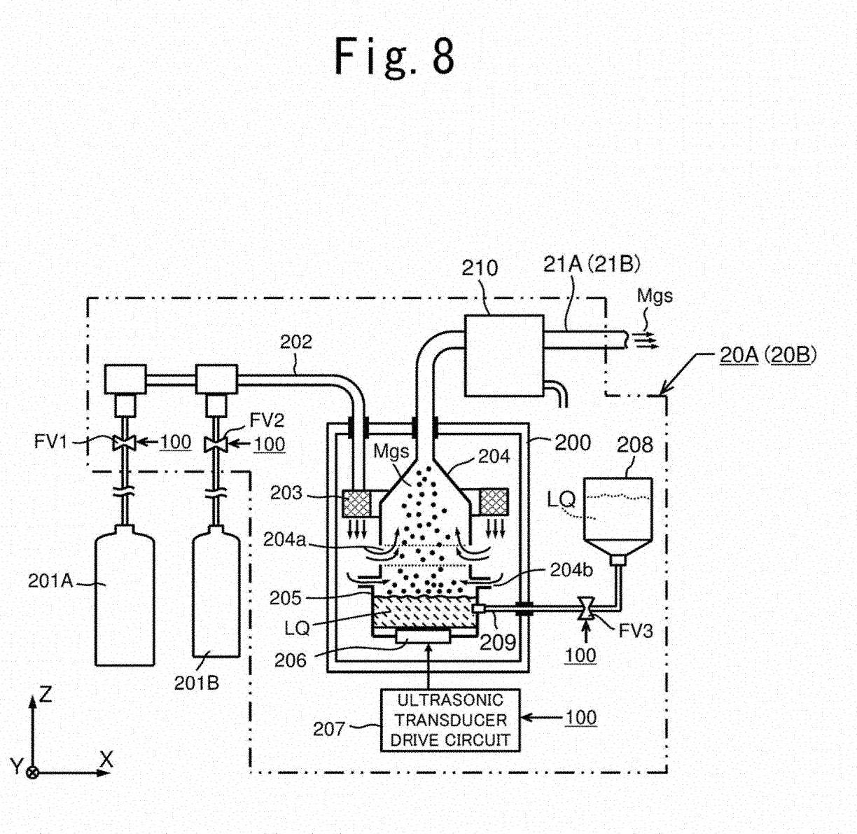

FIG. 8 shows an example of the configuration of the mist generation unit 20A (as well as 20B) in FIG. 5, where the mist gas Mgs supplied to the mist ejection unit 22A (22B) via the duct 21A (21B) is produced in a hermetically sealed mist generation chamber 200. A first carrier gas for the mist gas Mgs is fed from a cylinder 201A via a flow rate regulation valve FV1 to a pipe 202, and a second carrier gas therefor is fed from a cylinder 201B via a flow rate regulation valve FV2 to the pipe 202. One of the first carrier gas and the second carrier gas is oxygen, and the other is, for example, argon (Ar) gas. The flow regulation valves FV1, FV2 regulate the gas flow rates (pressures) in response to instructions from the main control unit 100 in FIG. 5.

The carrier gas (for example, a mixed gas of oxygen and argon) fed from the pipe 202 is supplied to a ring-shaped (annular in the XY plane) laminar flow filter 203 provided in the mist generation chamber 200. The laminar flow filter 203 ejects a carrier gas that has a substantially uniform flow rate in an annular distribution, toward the downward direction (−Z direction) in FIG. 8. The center space of the laminar flow filter 203 is provided with a funnel-shaped collecting unit 204 that collects the mist gas Mgs and puts the collected gas into the duct 21A (21B). The outer periphery of a cylindrical lower part of the collecting unit 204 is provided with windows (openings) 204a at an appropriate interval in the circumferential direction, through which the carrier gas from the laminar flow filter 203 flows into the lower part.

A solution tank 205 for storing a predetermined volume of precursor LQ that is a solution for mist generation is provided below the collecting part 204 with appropriate openings 204b in the Z direction. An ultrasonic transducer 206 is provided at the bottom of the solution tank 205, and driven by a drive circuit 207 in accordance with a high-frequency signal at a certain frequency. The vibration of the ultrasonic transducer 206 generates a mist from the surface of the precursor LQ, and the mist is mixed with the carrier gas in the collecting unit 204 to serve as mist gas Mgs, which is guided to the duct 21A (21B) via a trap 210. The trap 210 filters the mist diameter in the mist gas Mgs flowing from the collecting unit 204, to a predetermined size or less, and puts the filtered mist into the duct 21A (21B). In addition, into the solution tank 205, the precursor LQ stored in a reserve tank 208 is supplied via a flow rate regulation valve FV3 and a pipe 209.

The drive circuit 207 for the ultrasonic transducer 206 is capable of adjusting the drive frequency and the magnitude of vibration, based on an instruction from the main control unit 100, and the flow rate regulation valve FV3 regulates the flow rate, based on an instruction from the main control unit 100, so as to make the volume (the position at a liquid surface height) of the precursor LQ in the solution tank 205 substantially constant. For this purpose, the solution tank 205 is provided with a sensor for measuring the volume or weight of the precursor LQ or the liquid surface height thereof, and based on the measurement result of the sensor, the main control unit 100 outputs, to the flow rate regulation valve FV3, an instruction (an instruction for opening time or closing time).

In this manner, the volume of the precursor LQ in the solution tank 205 is kept substantially constant, thereby reducing the fluctuation in the resonance frequency of the precursor LQ, and making it possible to maintain an optimum mist generation efficiency. Of course, it is also possible to adjust the vibration frequency and amplitude condition of the ultrasonic transducer 206 in a dynamic manner in accordance with the change in the volume of the precursor LQ in the solution tank 205, thereby controlling the mist generation efficiency so as to be nearly unchanged. In addition, the precursor LQ is obtained by dissolving fine particles or molecules (ions) of a specific substance in pure water or a solvent solution at an appropriate concentration, and when the specific substance precipitates in pure water or a solvent solution, it is preferable to provide a function of stirring the precursor LQ in the reserve tank 208 (and the solution tank 205).

Furthermore, the inside or outer wall of the mist generation chamber 200 shown in FIG. 8, or the periphery of the collecting unit 204, is also provided with a temperature regulator (heater 23) for setting the mist gas Mgs generated from the collecting unit 204 to a predetermined temperature.

[High-Voltage Pulse Power Supply Unit 40]

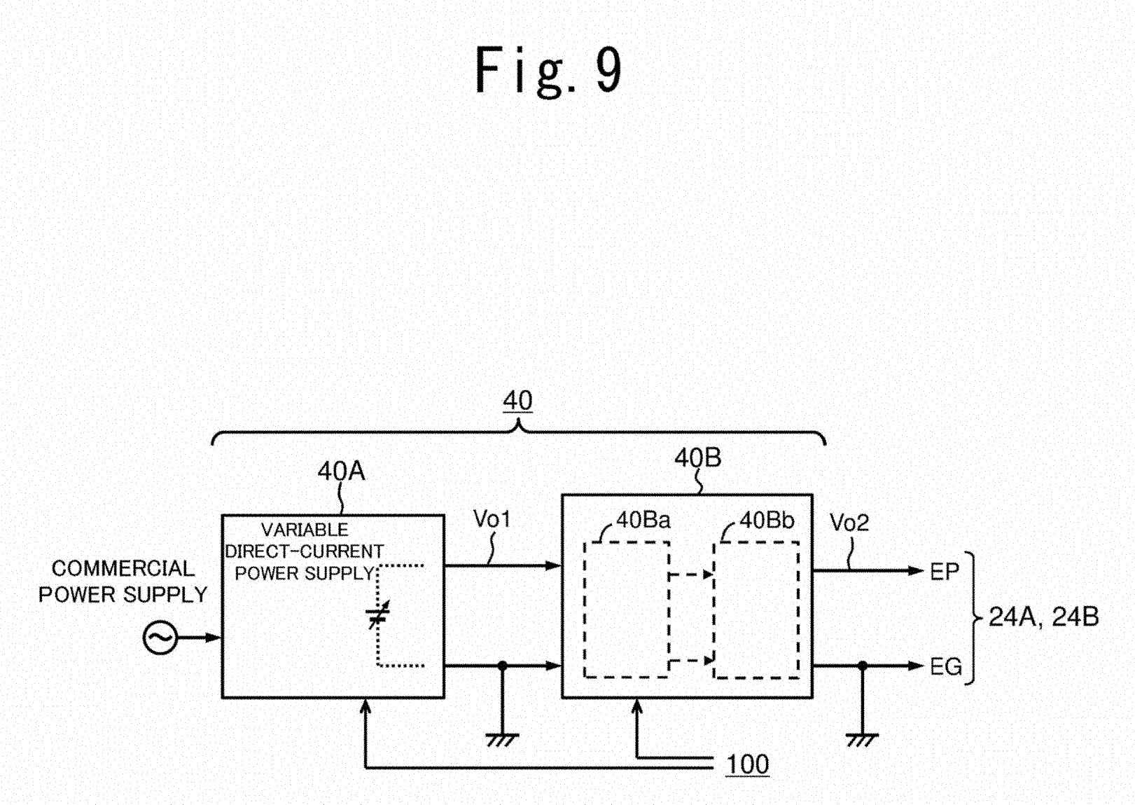

FIG. 9 is a block diagram illustrating an example of a schematic configuration of the high-voltage pulse power supply unit 40, which is composed of a variable direct-current power supply 40A and a high-voltage pulse generation unit 40B. The variable direct-current power supply 40A inputs a commercial alternating-current power supply of 100 V or 200 V, and outputs a smoothed direct-current voltage Vo1. The voltage Vo1 is made variable between 0 V and 150 V, for example, and also referred to as a primary voltage since the voltage serves as a power supply to the high-voltage pulse generation unit 40B in the next stage. The high-voltage pulse generation unit 40B is provided therein with a pulse generation circuit section 40Ba that repeatedly generates a pulse voltage (a rectangular short pulse wave whose peak value is approximately the primary voltage Vo1) corresponding to the frequency of the high-voltage pulse voltage applied between the wire-like electrodes EP, EG, and a boosting circuit section 40Bb that generates, in response to the pulse voltage, a high-voltage pulse voltage whose rise time and pulse duration are extremely short as an inter-electrode voltage Vo2.

The pulse generation circuit section 40Ba is composed of a semiconductor switching element and the like which turn on/off the primary voltage Vo1 at high speed at a frequency f. The frequency f is set to several KHz or less, but the rise time/fall time of the pulse waveform obtained by switching is set to several tens nS or less, and the pulse duration is set to several hundreds nS or less. The boosting circuit section 40Bb is intended to boost such a pulse voltage by about 20 times, and composed of a pulse transformer or the like.

The pulse generation circuit section 40Ba and the boosting circuit section 40Bb, by way of example only, may have any configuration as long as a pulse voltage with a peak value on the order of 20 kV, pulse rise time of about 100 nS or less, and a pulse duration of several hundreds nS or less can be continuously generated at the frequency f of several kHz or less as the final inter-electrode voltage Vo2. The higher the inter-electrode voltage Vo2 is, the larger the interval Lb (and the width Lc) between the pair of electrodes 24A (24B) shown in FIG. 7 is allowed to be, thereby making it possible to expand, in the Xt direction, the region on the substrate FS where the mist gas Mgs is ejected, and thus increase the film formation rate.

Further, in order to adjust the generation of plasma in a non-thermal equilibrium state between the pair of electrodes 24A (24B), the variable direct-current power supply 40A has such a function of varying the primary voltage Vo1 (i.e., an inter-electrode voltage Vo2) in response to an instruction from the main control unit 100, and the high-voltage pulse generation unit 40B has such a function of varying the frequency f of the pulse voltage applied between the pair of electrodes 24A (24B) in response to an instruction from the main control unit 100.

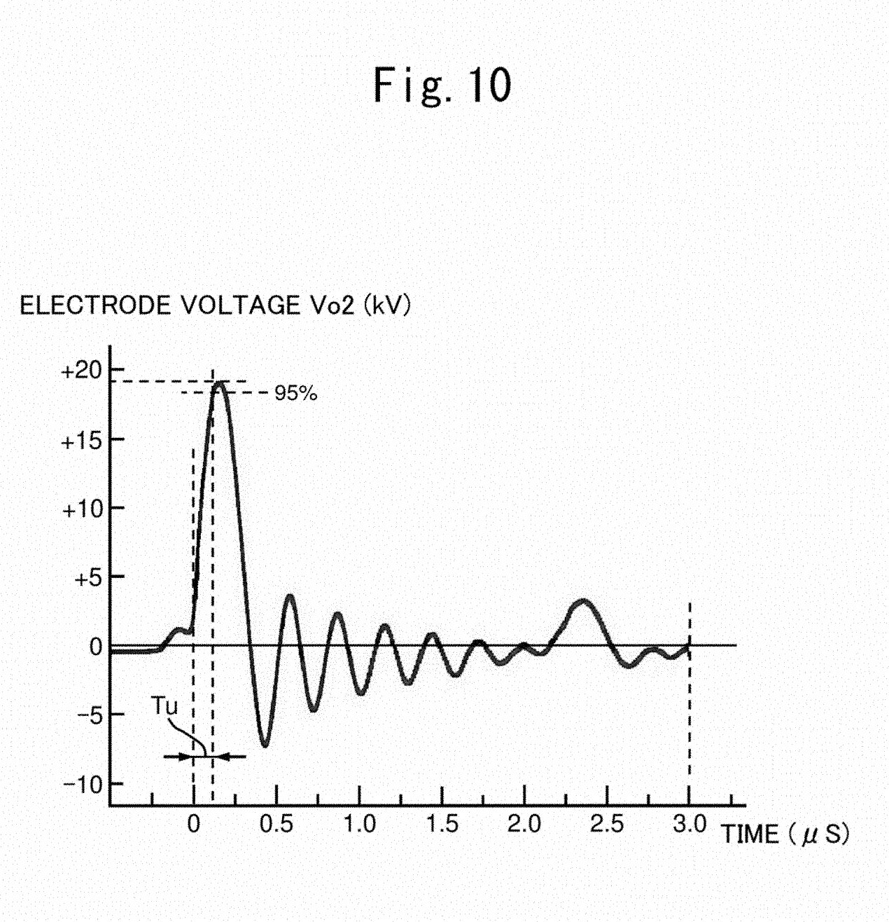

FIG. 10 shows an example of waveform characteristics of the inter-electrode voltage Vo2 obtained by the high-voltage pulse power supply unit 40 configured as shown in FIG. 9, where the vertical axis represents a voltage Vo2 (kV) and the horizontal axis represents time (μS). The characteristics in FIG. 10 show the waveform of one pulse of the inter-electrode voltage Vo2 obtained in the case of the primary voltage Vo1 of 120 V and the frequency f of 1 kHz, where a pulse voltage Vo2 of about 18 kV is obtained as a peak value. Furthermore, the rise time Tu from 5% to 95% of the first peak value (18 kV) is about 120 nS. In addition, in the circuit configuration of FIG. 9, a ringing waveform (attenuation waveform) is generated up to 2 μS after the waveform (pulse duration is about 400 nS) at the first peak value, but the voltage waveform at this part never lead to the generation of plasma in a non-thermal equilibrium state or arc discharge.

In the case of the previously exemplified configuration example of the electrodes, or of placing the electrodes EP, EG covered with the quartz tubes Cp1, Cg1 of 3 mm in outer diameter and 1.6 mm in inner diameter at the interval Lb=5 mm, the waveform part at the first peak value as shown in FIG. 10 is repeated at the frequency f, thereby stably and continuously generating atmospheric pressure plasma in a non-thermal equilibrium state is in the region PA (FIG. 7) between the pair of electrodes 24A (24B).

[Heater Units 27A, 27B]

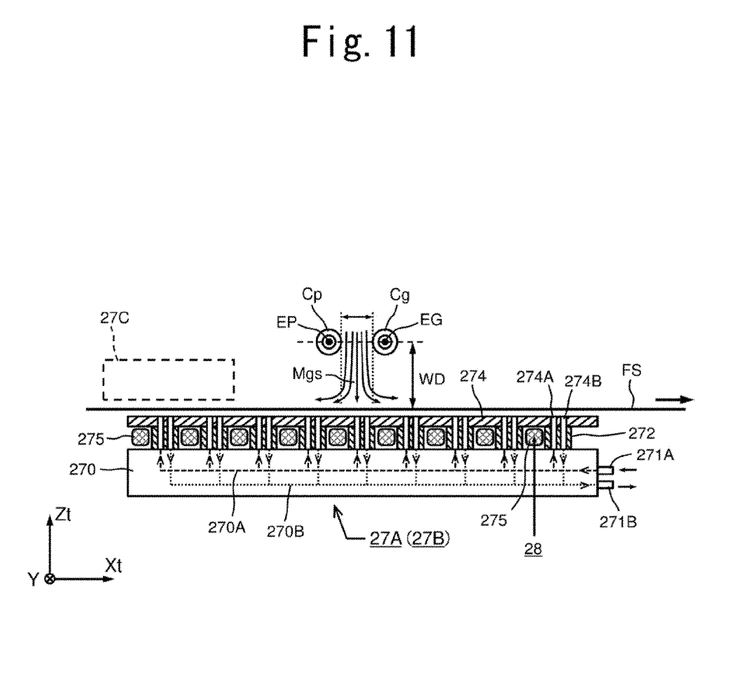

FIG. 11 is a cross-sectional view illustrating an example of the configuration of the heater unit 27A (as well as 27B) in FIG. 5. Since the sheet substrate FS is continuously conveyed at a constant speed (for example, several mm to several cm per minute) in the longitudinal direction (+Xt direction), there is a possibility of scratching the back surface of the substrate FS, with the upper surface of the heater unit 27A (27B) in contact with the back surface of the sheet substrate FS. Therefore, according to the present embodiment, a gas layer of air bearing with a thickness on the order of several μm to several tens μm is formed between the upper surface of the heater unit 27A (27B) and the back surface of the substrate FS such that the substrate FS is fed in a non-contact state (or low friction state).

The heater unit 27A (27B) is composed of a base 270 opposed to the back surface of the substrate FS, spacers 272 at a fixed height, provided in multiple locations on the base 270 (+Zt direction), a flat metallic plate 274 provided on the plurality of spacers 272, and a plurality of heaters 275 provided between the plurality of spacers 272, and between the base 270 and the plate 274.

The plurality of spacers 272 is each formed with a gas injection hole 274A that penetrates up to the surface of the plate 274 and an air suction hole 274B for gas suction. The ejection hole 274A penetrating through each spacer 272 is connected to a gas introduction port 271A via a gas flow path formed in the base 270, and the air suction hole 274B penetrating through each spacer 272 is connected to a gas exhaust port 271B through a gas flow path formed in the base 270. The introduction port 271A is connected to a source of pressurized gas supply, and the exhaust port 271B is connected to a reduced pressure source for creating a vacuum pressure.

The surface of the plate 274 is provided with the ejection hole 274A and the air suction hole 274B close to each other within the Y·Xt plane, the gas ejected from the ejection hole 274A is thus immediately suctioned into the air suction hole 274B. Thus, a gas layer of air bearing is formed between the flat surface of the plate 274 and the back surface of the substrate FS. When the substrate FS is conveyed with predetermined tension in the longitudinal direction (Xt direction), the substrate FS keeps itself flat to follow the surface of the plate 274.

Additionally, since the gap between the surface of the plate 274 which is heated by the heat generated by the plurality of heaters 275 and the back surface of the substrate FS is only about several μm to several tens μm, the substrate FS is immediately heated to a set temperature by radiant heat from the surface of the plate 274. The set temperature is controlled by the temperature control unit 28 shown in FIG. 5.

In addition, when there is a need for heating not only from the back surface of the substrate FS but also from the upper surface (processed surface) side, a heating plate (the set of plate 274 and heater 275 in FIG. 11) 27C opposed to the upper surface of the substrate FS at a predetermined gap is provided upstream of the region where the mist gas Mgs is ejected with respect to the conveying direction of the substrate FS.

As described above, the heater unit 27A (27B) has both a temperature control function of heating a part of the substrate FS subjected to the jet of mist gas Mgs, and a non-contact (low friction) support function of floating the substrate FS by the air bearing method, and thus supporting the substrate FS to be flat. The working distance WD in the Zt direction between the upper surface of the substrate FS and the pair of electrodes 24A (24B) as shown in FIG. 7 is desirably kept constant even in the process of conveying the substrate FS in order to maintain the film thickness uniformity during film formation. As shown in FIG. 11, since the heater unit 27A (27B) according to the present embodiment supports the substrate FS with vacuum pressurized air bearing, the gap between the back surface of the substrate FS and the upper surface of the plate 274 is kept substantially constant, thereby suppressing the positional fluctuation of the substrate FS in the Zt direction.

As just above, in the thin film manufacturing device 1 configured according to the present embodiment (FIGS. 5 to 11), while the substrate FS is conveyed at a constant speed in the longitudinal direction, the high-voltage pulse power supply unit 40 is operated to generate atmospheric pressure plasma in a non-thermal equilibrium state between the pair of electrodes 24A, 24B, and the mist gas Mgs is ejected at a predetermined flow rate from the aperture SN of the mist ejection units 22A, 22B. The mist gas Mgs that has passed through the region PA (FIG. 7) where atmospheric pressure plasma is generated is ejected to the substrate FS, and the specific substance the mist of the mist gas Mgs contains therein is continuously deposited on the substrate FS.

According to the present embodiment, the arrangement of the two mist ejection units 22A, 22B in the conveying direction of the substrate FS doubly improves the film formation rate of a thin film of the specific substance deposited on the substrate FS. Therefore, the film formation rate is further improved by increasing the mist ejection units 22A, 22B in the conveying direction of the substrate FS.

Further, according to the present embodiment, the mist generation units 20A and 20B are individually provided respectively for the mist ejection units 22A and 22B, and the heater units 27A and 27B are individually provided therefor. Therefore, the mist gas Mgs ejected from the aperture SN of the mist ejection unit 22A and the mist gas Mgs ejected from the aperture SN of the mist ejection unit 22B can be varied in properties (the content concentration of a specific substance in the precursor LQ, the ejection flow rate and temperature of the mist gas, etc.), and the temperature of the substrate FS can be varied. The film formation conditions (film thickness, flatness, etc.) can be adjusted by varying the properties of the mist gas Mgs ejected from the aperture SN for each of the mist ejection units 22A, 22B and the temperature of the substrate FS.

Since the thin film manufacturing device 1 in FIG. 5 is intended to convey the substrate FS independently by the roll-to-roll method, the film formation rate can be adjusted also by changing the conveyance speed of the substrate FS. However, it may be difficult to change the conveyance speed of the substrate FS in some cases, when a pre-process device is connected which applies base processing or the like to the substrate FS before forming a film by the thin film manufacturing device 1 as in FIG. 5, or when a post-process device is connected which applies a treatment such as applying a photosensitive resist, a photosensitive silane coupling material, or the like immediately to the substrate FS with the film formed. Even in such a case, the thin film manufacturing device 1 according to the present embodiment can adjust the film formation conditions, so as to be suitable for the set conveyance speed of the substrate FS.

Of course, the mist gas Mgs generated by one mist generation unit 20A may be distributed and supplied to each of the two mist ejection units 22A, 22B, or more mist ejection units.

It is to be noted that while the configuration for supplying the mist gas Mgs to the substrate FS from the Zt direction has been described in the present embodiment, the present invention is not limited thereto, but any configuration for supplying the mist gas Mgs to the substrate FS from the −Zt direction may be adopted. In the case of a configuration for supplying the mist gas Mgs to the substrate from the Zt direction, there is a possibility that the droplets accumulated in the mist ejection units 22A, 22B will fall onto the substrate FS, which can be suppressed by adopting a configuration for supplying the mist gas Mgs to the substrate FS from the −Zt direction. Which direction the mist gas Mgs is supplied from may be determined appropriately depending on the supply amount of the mist gas Mgs and other manufacturing conditions.

### MODIFIED EXAMPLE OF MIST EJECTION UNIT 22A (22B)

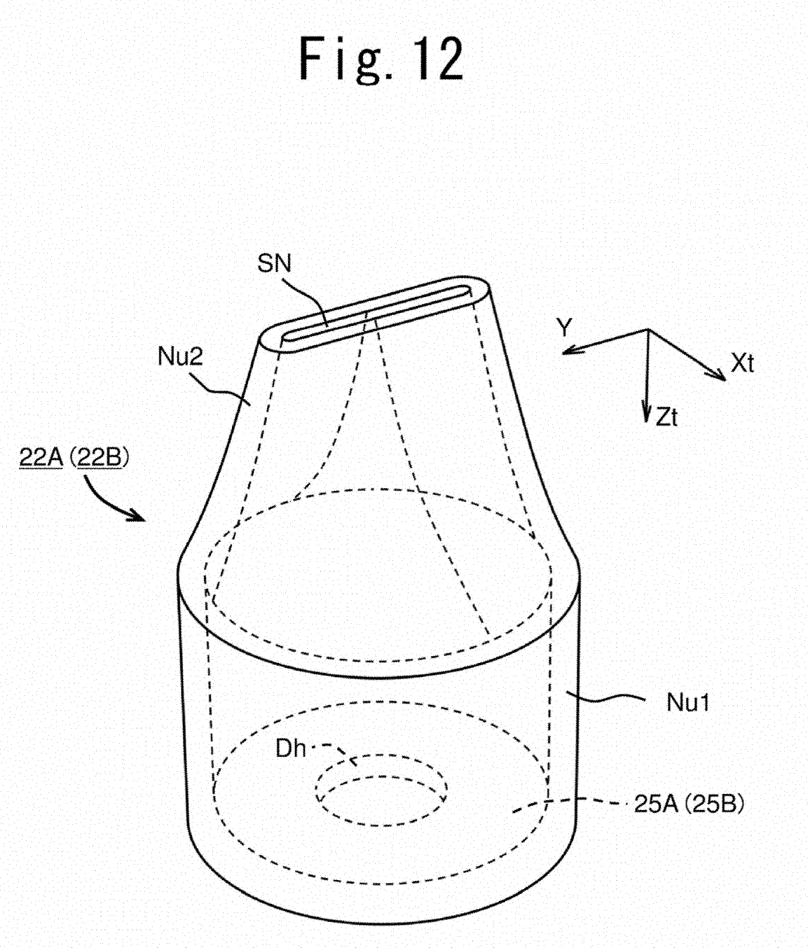

FIG. 12 shows a modified example of the mist ejection unit 22A (22B) shown in FIG. 6, which is a perspective view as seen from the −Zt side of the coordinate system Xt·Y·Zt, that is, from the substrate FS side as with FIG. 6. In this modified example, the mist ejection unit 22A (22B) has a circular top board 25A (25B) with an opening Dh connected to a duct 21A (21B), and includes a quartz circular tube part Nu1 coupled to the top board 25A (25B) in the −Zt direction, and a quartz funnel part Nu2 formed continuously from the circular tube part Nu1 in the −Zt direction and shaped in the form of a nozzle such that a slot-like aperture SN extending in the Y direction is formed at the tip in the −Zt direction. The circular tube part Nu1 and the funnel part Nu2 may be made by integrally shaping a quartz circular tube with a predetermined thickness, or may be made by attaching separately prepared parts. In the case of the present modified example, in order to control the temperature of the mist gas Mgs supplied from the opening Dh, the heater 23A (23B) as shown in FIG. 5 is disposed annularly around the circular tube part Nu1.

Also in the mist ejection unit 22A (22B) of FIG. 12, similarly as shown in FIG. 6, a pair of electrodes 24A (24B) extending in the Y direction is arranged parallel so as to sandwich a slot-like aperture SN in the Xt direction, and fixed to the tip of the funnel part Nu2 in the −Zt direction.

In the mist ejection unit 22A (22B) as in the modified example of FIG. 12, the shape obtained when the internal space is cut along a plane parallel to the Y·Xt plane is smoothly changed from a circular shape to a slot shape as viewed from the opening Dh side, and the mist gas Mgs which spreads from the opening Dh into the inner space is thus smoothly converged toward the slot-like aperture SN. Thus, it is possible to improve the uniformity of the mist concentration (for example, the mist number per 1 cm³) of the mist gas Mgs ejected from the slot-like aperture SN.

### Fourth Embodiment

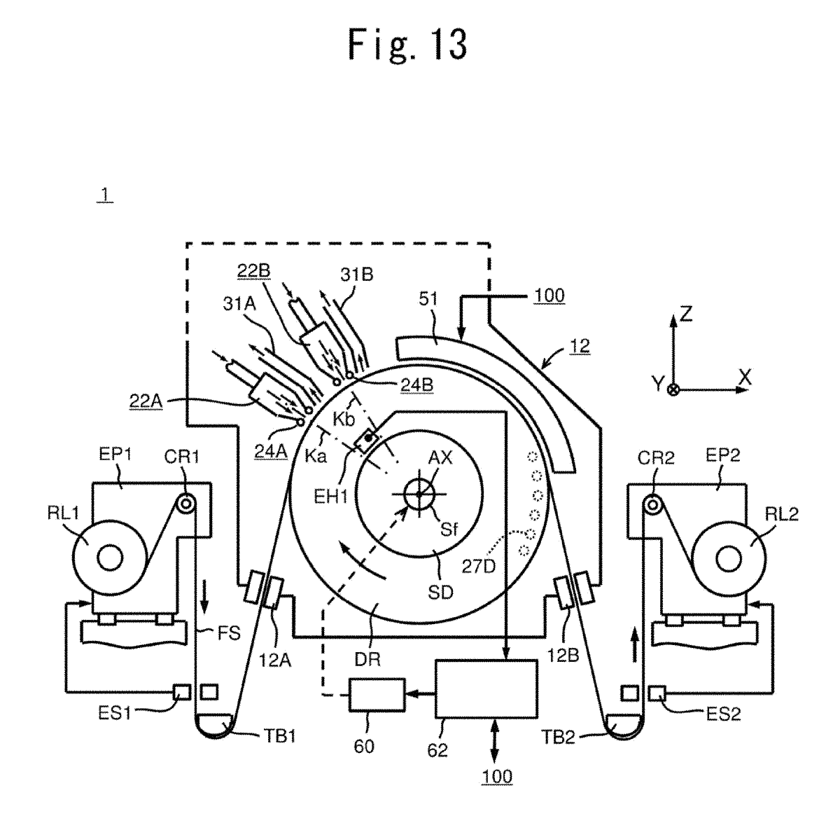

FIG. 13 schematically shows the overall configuration of a thin film manufacturing device 1 according to a fourth embodiment. In the device configuration of FIG. 13, the same constituent parts, units and members as those of the thin film manufacturing device 1 (FIGS. 5 to 11) according to the first embodiment are denoted by the same reference numerals, and descriptions thereof will be omitted partially. According to the fourth embodiment, a sheet substrate FS is conveyed in the longitudinal direction in close contact with and supported by a part of the outer peripheral surface of a cylindrical or columnar rotary drum DR with a predetermined diameter, which is rotatable around a center line AX extending in the Y direction, and a specific substance is deposited by a mist CVD method or a mist deposition method onto the substrate FS supported by the rotary drum DR in the form of a cylindrical surface.

The rotary drum DR is rotationally driven clockwise in the figure by a motor unit 60 connected to a shaft Sf that is coaxial with the center line AX. The motor unit 60 is composed of a combination of a normal rotary motor and a reduction gearbox, or a low-speed rotation/high torque-type direct drive (DD) motor that has a rotation axis directly connected to the shaft Sf. The rotation speed of the rotary drum DR is determined by the conveyance speed of the sheet substrate FS in the longitudinal direction and the diameter of the rotary drum DR. The motor unit 60 is controlled by a servo drive circuit 62 so that the rotation speed of the rotary drum DR or the peripheral speed of the outer peripheral surface of the rotary drum DR reaches a specified target value. The target value of the rotational speed or circumferential speed is set from the main control unit 100 shown in FIG. 5.

The shaft Sf of the rotary drum DR has a scale disk SD for encoder measurement attached coaxially thereto to rotate integrally with the rotary drum DR. The outer peripheral surface of the scale disc SD has a grid-like scale (scale pattern) formed over the entire circumference at a constant pitch in the circumferential direction thereof. The rotational position of the scale disc SD (the rotational position of the rotary drum DR) is opposed to the outer peripheral surface of the scale disc SD, and measured by an encoder head part EH1 (hereinafter, referred to simply as a head part EH1) that optically reads changes in the circumferential direction of the scale pattern.

From the head part EH1, two-phase signals (sine wave signal and cosine wave signal) with a phase difference of 90° are output in response to the positional change of the scale pattern in the circumferential direction. The two-phase signal is converted into an up/down pulse signal by an interpolation circuit or a digitization circuit provided in the servo drive circuit 62, and the up/down pulse signal is counted by a digital counter circuit, thereby measuring the angular position of the rotation of the rotary drum DR as a digital value. The up/down pulse signal is set so as to generate one pulse each time the outer peripheral surface of the rotary drum DR moves in the circumferential direction, for example, by 1 μm. In addition, the digital value of the angular position of the rotary drum DR, measured by the digital counter circuit, is also transmitted to the main control unit 100, and used for checking the conveyance distance and conveyance speed of the sheet substrate FS.

In other words, according to the present embodiment, the substrate FS is guided to the mist ejection unit 22 via a substantially arc-like conveying path.

The mist ejection unit 22A shown in FIG. 6 previously, or in FIG. 12 is placed in the thin film manufacturing device 1 according to the present embodiment to, as viewed in the XZ plane, eject a mist gas Mgs along a line segment Ka tilted at on the order of 30° to 45° with respect to the XY plane through the center line AX, and the mist ejection unit 22B, away therefrom in the conveying direction of the substrate FS, is placed to, as viewed in the XZ plane, eject the mist gas Mgs along a line segment Kb tilted at on the order of 45° to 60° with respect to the XY plane through the center line AX. The surface of the sheet substrate FS at the position where the line segment Ka intersects with the sheet substrate FS is inclined at on the order of 60° to 45° with respect to the XY plane, whereas the surface of the sheet substrate FS at the position where the line segment Kb intersects with the sheet substrate FS is inclined at on the order of 45° to 30° with respect to the XY plane. The encoder head part EH1 is provided in an angular position between the two line segments Ka, Kb.

According to the present embodiment, gas collection ducts 31A and 31B are provided so that the mist gas Mgs ejected from slot-like apertures SN at the respective tips of the mist ejection units 22A and 22B flows in the same manner on the substrate FS. A slot-like suction port, which is an opening on the side close to the rotary drum DR, of the gas collection ducts 31A, 31B, is located in an upward (+Z direction) position lateral to the conveying direction of the substrate FS with respect to the apertures SN at the tips of the mist ejection units 22A, 22B.

The approximate inclination of the surface of the substrate FS onto which the mist gas Mgs from the aperture SN of the mist ejection unit 22A is ejected with respect to the XY plane (the inclination of the tangential plane with respect to the horizontal plane) is larger than the approximate inclination of the surface of the substrate FS onto which the mist gas Mgs from the aperture SN of the mist ejection unit 22B is ejected with respect to the XY plane. Therefore, the mist gas Mgs ejected from the mist ejection unit 22A onto the substrate FS tries to flow faster in the direction of gravity (−Z direction) along the surface of the substrate FS, as compared with the mist gas Mgs ejected from the mist ejection unit 22B onto the substrate FS.

Therefore, individually regulating the flow rate (negative pressure) suctioned from the suction port of the gas collection duct 31A and the flow rate (negative pressure) suctioned from the suction port of the gas collection duct 31B allows the mist gas Mgs from each of the mist ejection units 22A, 22B to flow in the same manner on the substrate FS. The gas collection ducts 31A, 31B are connected to the exhaust control unit 30 shown in FIG. 5 via valves whose exhaust flow rates can be individually regulated.

In the case of the present embodiment as well, atmospheric pressure plasma in a non-thermal equilibrium state is generated by a pair of electrodes 24A, 24B provided on the apertures SN at the respective tips of the mist ejection units 22A, 22B. Thus, in the case of a mist deposition method, the mist in the mist gas Mgs immediately before being sprayed onto the substrate FS adheres onto the substrate FS as a plasma-assisted mist, thereby producing a thin liquid film including molecules or ions of a specific substance on the substrate FS. In the case of a mist CVD method, because the substrate FS is heated to about 200° C., the liquid component (pure water, solvent, etc.) of the plasma-assisted mist is vaporized immediately before the mist reaches the substrate FS, and the fine particles of the specific substance the mist contains therein the mist adhere to the surface of the substrate FS.

In the case of applying the mist CVD method, it is necessary to heat the substrate FS, and thus, according to the present embodiment, a large number of heaters 27D is buried in the circumferential direction near the outer peripheral surface in the rotary drum DR, thereby providing a function of heating the outer peripheral surface of the rotary drum DR to about 200° C. over the entire circumference of the peripheral surface. In such a case, in order to avoid heating of the entire rotary drum DR, the rotary drum DR has a multi-tube structure composed of a first cylindrical member that is outermost metallic to support the substrate FS, a second cylindrical member provided inside the first cylindrical member to support the heaters 27D, a third cylindrical member provided further inside a second cylindrical member to insulate heat from the heaters 27D, and a fourth cylindrical member with a shaft Sf, provided further inside a third cylindrical member.

In the case of applying the mist deposition method, it is unnecessary to heat the substrate FS to a relatively high temperature with the heaters 27D in the rotary drum DR, but the surface of the substrate FS is wet with a thin liquid film due to the mist adhering to the substrate FS, and a drying/temperature control unit 51 which is similar to the drying unit (heating unit) 50 shown in FIG. 5 is provided at the position opposed to the rotary drum DR downstream of the mist ejection units 22A, 22B with respect to the conveying direction of the substrate FS, thereby evaporating the liquid component adhering to the substrate FS. The drying/temperature control unit 51 is provided in an arc form along the outer peripheral surface of the rotary drum DR, to dry the substrate FS with radiation heat from the heaters, infrared irradiation from an infrared light source, a jet of hot air, or the like under the control of the main control unit 100.

As in FIG. 13, the rotary drum DR, the mist ejection units 22A, 22B, the drying/temperature control unit 51, and the like are provided in the second chamber 12 also shown in FIG. 5, and the gas distribution through an inlet port and an outlet port for the substrate FS between the internal space of the second chamber 12 and the external space is blocked by slit-like air-sealing parts 12A, 12B. In addition, in order to collect the mist gas Mgs remaining in the second chamber 12 of FIG. 13, a duct 12C, not shown, which is similar to FIG. 5, is connected to the exhaust control unit 30.

In FIG. 13, the apertures SN that ejects the mist gases of the mist ejection units 22A, 22B are configured to be positioned above the center line AX as the rotation center of the rotary drum DR, but the vertical relationship may be reversed. More specifically, the rotary drum DR, the mist ejection units 22A and 22B, the gas collection ducts 31A, 31B, and the drying/temperature control unit 51 in FIG. 13 may be rotated by 180° around the X axis to dispose the mist ejection units 22A, 22B and the gas collection ducts 31A, 31B below the rotary drum DR. In this case, a conveying path is provided such that the sheet substrate FS is supplied downward from above the rotary drum DR (+Z direction), supported by the outer peripheral surface of about the lower half of the rotary drum DR, and then discharged upward.

When the substrate FS is conveyed while being supported on the outer peripheral surface of the rotary drum DR as in the present embodiment, the surface of the substrate FS can be periodically displaced in the directions of the line segments Ka, Kb, due to a roundness error of the rotary drum DR, an eccentric error of the shaft Sf, a deviation of a bearing, and the like. However, since the tolerances of the roundness error and eccentric error and the deviation of the bearing in manufacturing the rotating body are reduced to about ±several μm at most, the working distance WD explained with FIG. 7 nearly unchanged, and the surface of the substrate FS, curved in a cylindrically planar form in the conveying direction, is stably fed in the longitudinal direction.

Furthermore, when the substrate FS before entering the rotary drum DR has slight waviness (undulation in the normal direction of the substrate surface) in the width direction (Y direction), such waviness (undulation) can be eliminated, because the tension of the substrate FS causes the substrate FS to try to come into close contact with the outer peripheral surface of the rotation drum DR. When film formation is performed by a mist CVD method or a mist deposition method while the substrate FS waviness (undulation) generated, there is a possibility that the distance from the slot-like aperture SN of the mist ejection unit 22A, 22B to the surface of the substrate FS will not be uniform in the longitudinal direction (Y direction) of the aperture SN, thereby causing unevenness in film thickness. According to the present embodiment, the substrate FS is closely supported by the rotary drum DR, thus keeping the substrate FS from having waviness (undulation) generated, and making unevenness in film thickness unlikely to be caused.

### Fifth Embodiment

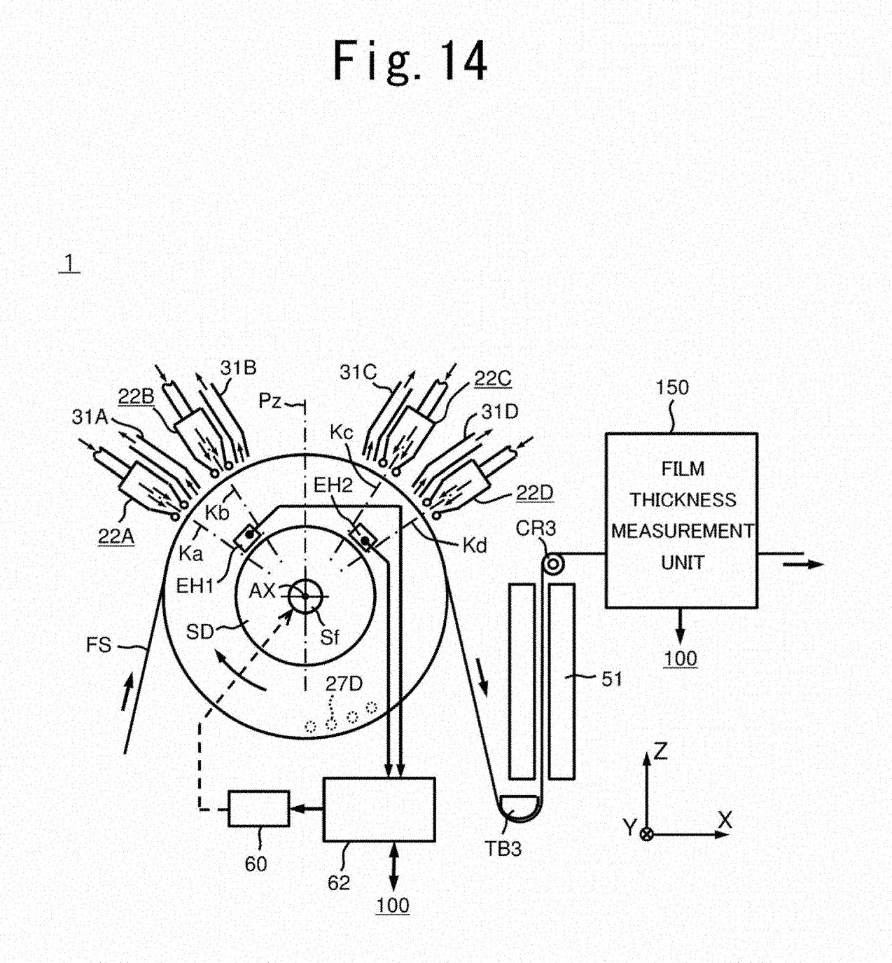

FIG. 14 schematically shows the overall configuration of a thin film manufacturing device 1 according to a fifth embodiment. While continuously conveying a substrate FS with the use of a rotary drum DR, two additional mist ejection units 22C, 22D and gas collection ducts 31C, 31D are provided downstream of the two mist ejection units 22A, 22B in FIG. 13, thereby further improving the film formation rate.

The set of the mist ejection unit 22C and the gas collection duct 31C is arranged symmetrical to the set of the mist ejection unit 22B and the gas collection duct 31B with respect to a center plane Pz including the center line AX and parallel to the YZ plane, and the set of the mist ejection unit 22D and the gas collection duct 31D is arranged symmetrical to the set of the mist ejection unit 22A and the gas collection duct 31A with respect to the center plane Pz. Accordingly, a line segment Kc parallel to the jet direction of the mist gas Mgs from the mist ejection unit 22C is positioned symmetrical to the line segment Kb with respect to the center plane Pz, and a line segment Kd parallel to the jet direction of the mist gas Mgs from the mist ejection unit 22D is positioned symmetrical to the line segment Ka with respect to the center plane Pz. A second encoder head part EH2 is provided in an angular position between the line segment Kc and the line segment Kd.

According to the present embodiment, the substrate FS supported by the rotary drum DR is passed sequentially under the four mist ejection units 22A, 22B, 22C, 22D, and fed via an air turn bar TB3 and a roller CR3 to a drying/temperature control unit 51. The drying/temperature control unit 51 is mainly used for drying the substrate FS processed by a mist deposition method under ordinary temperature, but may be also used for heat removal (cooling) of the substrate FS processed by a mist CVD method under high temperature. The substrate FS which has been passed through the drying/temperature control unit 51 is carried into a film thickness measurement unit 150. The film thickness measurement unit 150 measures, almost in real time, the average thickness of a thin film of a specific substance formed on the substrate FS, the thickness variation of the substrate FS in the longitudinal direction, thickness unevenness of the substrate FS in the width direction, etc., while the substrate FS moves, and transmits the measurement results to the main control unit 100.

The position of the film thickness to be measured in the longitudinal direction on the sheet substrate FS is specified from the measurement values provided by encoder head parts EH1, EH2. In addition, within the film thickness measurement section 150, an information writing mechanism may be provided which, when it is determined that the average film thickness value or thickness unevenness of the measured part is regarded a defective part in excess of the allowable range, puts stamps (ink-jet, laser markers, printing by imprinting or the like, incuse) representing the generation of defects, the presence of thickness unevenness, measured film thickness values, and the like in the vicinity of an end in the width direction, which corresponds to the position of the defective part appearance on the substrate FS. The stamps provided by the information writing mechanism may be one-dimensional or two-dimensional bar codes, or maybe unique patterns (symbols, figures, characters, etc.) that can be identified by the analysis of images captured by imaging elements. In addition, the film thickness measurement by the film thickness measurement unit 150 may be performed every time the substrate FS is fed by a certain distance in the longitudinal direction, for example, comparable to the interval Lb between the electrodes EP, EG.

When the film thickness or thickness unevenness sequentially measured by the film thickness measurement unit 150 shows a tendency to change gradually with respect to a target value (set value), as long as the change falls outside the allowable range, the main control unit 100 can control the operation conditions for respective units, for example, the flow rate of the mist gas Mgs injected from each of the mist ejection units 22A, 22B, 22C, 22D, the concentration and temperature of the mist gas Mgs, the condition of the high-voltage pulse voltage applied to each of pairs of electrodes 24A, 24B, 24C, 24D, or the temperatures of heaters 27D, etc. in an appropriate manner, thereby making a feedback correction such that the film thickness reaches the target value. It is to be noted that if such a feedback correction is arranged so that the film thickness measurement unit 150 can measure the substrate FS immediately after film formation, the film formation devices according to the first and second embodiments can even make the feedback correction in the same manner.

Furthermore, even onto the substrate FS stamped by the information writing mechanism which determines that the film thickness is thin outside the allowable range, additional film formation can be performed later in some cases, depending on the specific substance for film formation. In such a case, it is also possible to mount, as a supply roll RL1, a roll with the rolled-up substrate FS to be subjected to additional film formation, convey the substrate FS at high speed while continuously imaging a stamped part on the substrate FS by an imaging element (TV camera), and when the stamp appears in the image screen, return the feed speed of the substrate FS back to the set speed at the time of film formation, and perform additional film formation on the part.

According to the present embodiment, based on the measured condition of the film thickness, the flow rate, temperature, and concentration of the mist gas Mgs injected from each of the mist ejection units 22A, 22B, 22C, 22D, the condition of the high-voltage pulse voltage applied to each of the pairs of electrodes 24A, 24B, 24C, 24D, the heater temperature, and the like can be appropriately adjusted, thus making it possible to continue a high-quality film formation process with film thickness uniformity during continuous conveyance of the sheet substrate FS. This advantage is also achieved by providing the film thickness measurement unit 150, in the same manner as in the previous film formation device (FIGS. 5 to 11) according to the third embodiment and the film formation device (FIG. 13) according to the fourth embodiment.

### Sixth Embodiment

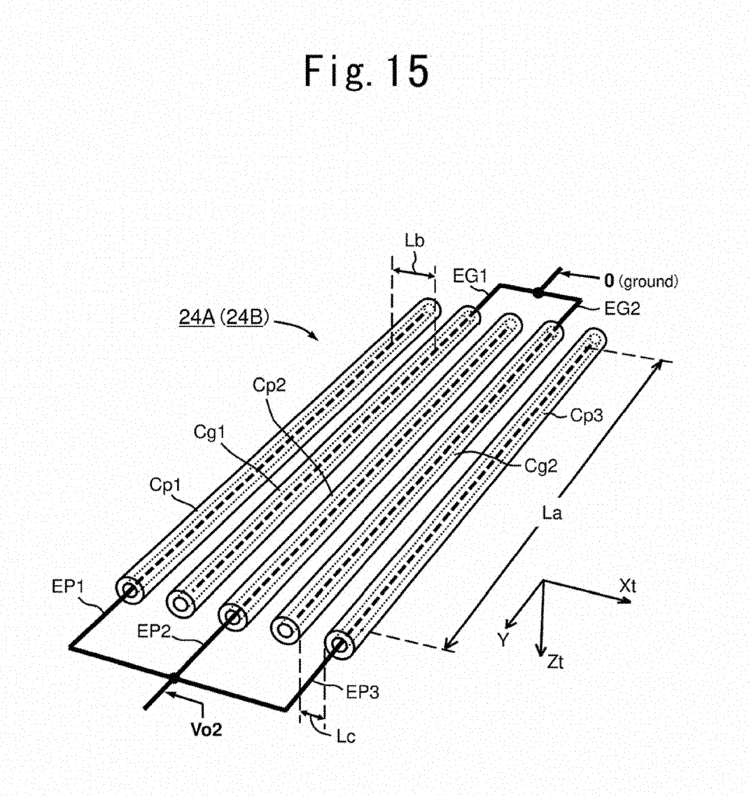

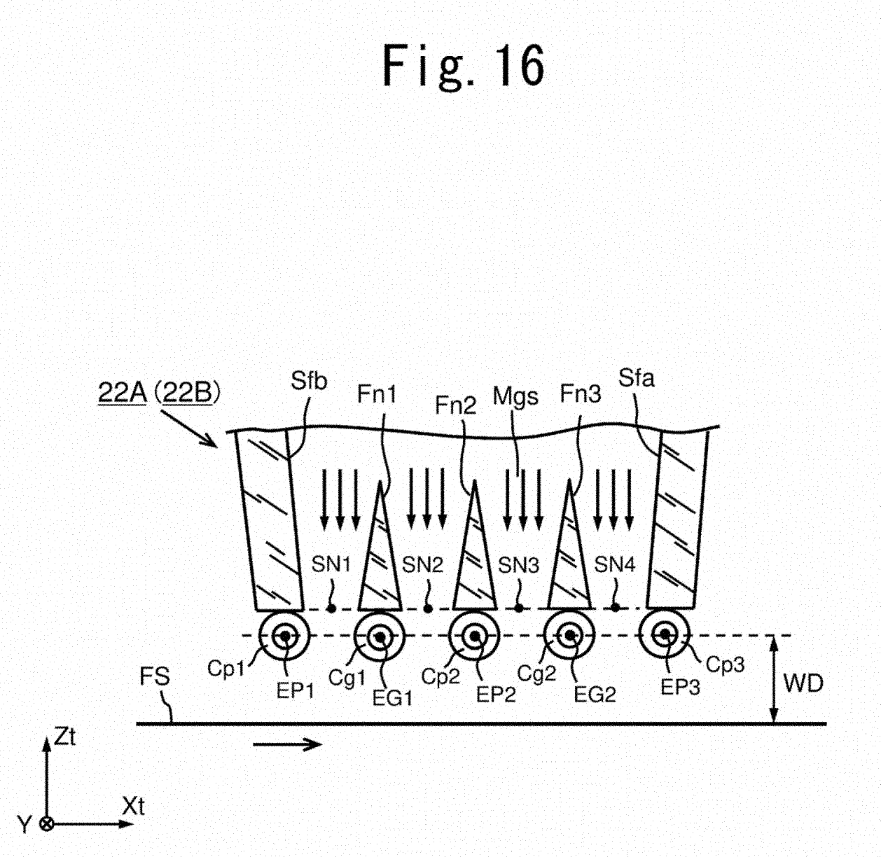

FIGS. 15 and 16 are diagrams illustrating an example of an electrode structure according to a sixth embodiment. According to this embodiment, as shown in FIG. 15, three wire-like electrodes EP1, EP2, EP3 to serve as positive electrodes, and two wire-like electrodes EG1, EG2 to serve as negative electrodes (ground) are alternately, in the order of positive electrode, negative electrode, positive electrode, . . . , arranged in parallel with each other at intervals Lb in the conveying direction (Xt direction) of the substrate FS. The electrodes EP1, EP2, EP3 are all connected to a positive electrode output (Vo2) of a high-voltage pulse power supply unit 40, and the electrodes EG1, EG2 are both connected to a negative electrode (ground). In addition, the five wire-like electrodes EP1 to EP3, EG1, EG2 are covered respectively with quartz tubes Cp1, Cp2, Cp3, Cg1, Cg2 that are equal in outer diameter and inner diameter, and the mist gas Mgs is injected to the substrate FS through each of four slot-like apertures (the plasma generation region PA shown in FIG. 7) formed between the quartz tubes Cp1 to Cp3, Cg1, Cg2, thereby improving the film formation rate.

FIG. 16 is a partial cross-sectional view of a mist ejection unit 22A (22B) with the electrode body of FIG. 15 attached to a tip of the unit, as viewed from the Y direction. The mist ejection unit 22A (22B) in FIG. 16 is configured to have the same shape as that in FIG. 6. However, the width of an aperture at the tip of the mist ejection unit 22A (22B) in the Xt direction (the interval in the Xt direction at the tip of inclined inner wall Sfa, Sfb in the −Zt direction) is set such that the five electrode bodies (the quartz tubes Cp1 to Cp3, Cg1, Cg2) are aligned. For example, when the outer diameter of each quartz tube is 3 mm, whereas the width Lc of the gap between the respective quartz tubes is 2 mm, the width of the aperture in the Xt direction at the tip of the mist ejection unit 22A (22B) is set to about 17 mm.

Furthermore, as shown in FIG. 16, at the aperture of the mist ejection unit 22A (22B), quartz fin members Fn1, Fn2, Fn3 that extend in a wedge form elongated in the +Zt direction (the width of the bottom surface in the Xt direction has a dimension comparable the outer diameter of the quartz tube) are disposed respectively on the three quartz tubes Cg1, Cp2, Cg2, and from each of the apertures SN1, SN2, SN3, SN4, the mist gas Mgs is distributed and injected in laminar flow.

In the configuration of FIGS. 15 and 16, the four pairs of electrodes to which a high-voltage pulse voltage is applied are provided in parallel in the Xt direction along the surface of the substrate FS (in the direction of the inter-electrode interval Lb), and the film formation region on the substrate FS is thus expanded by about 4 times in the Xt direction as compared with the arrangement of one pair of electrodes previously as shown in FIG. 6, thereby making it possible to increase the film formation rate by about 4 times.

### Seventh Embodiment

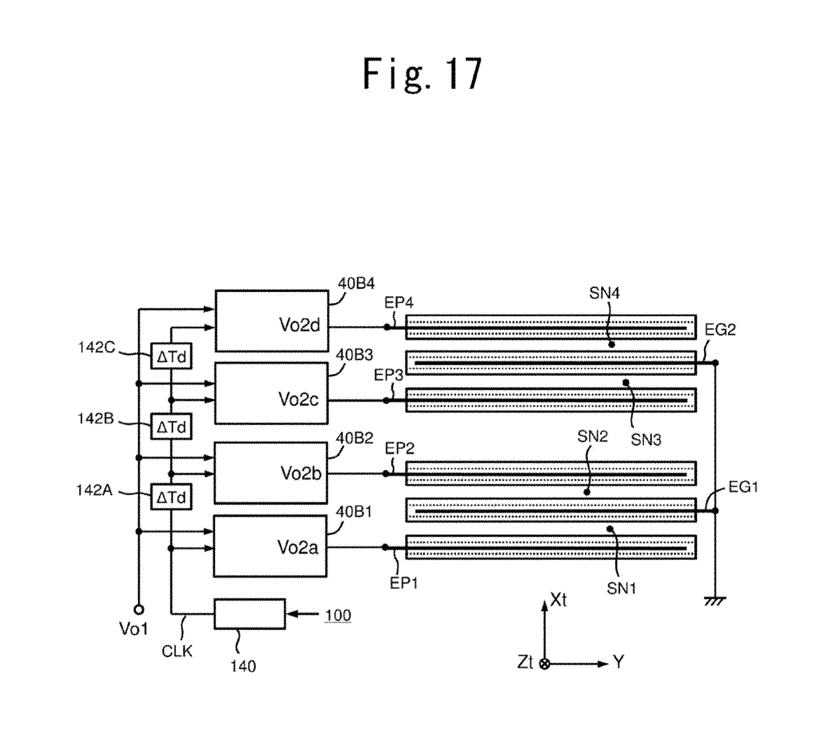

FIG. 17 is a block diagram illustrating an example of the configuration of an electrode structure and a power supply unit that implements a high-voltage pulse voltage application method according to a seventh embodiment. In FIG. 17, arranged in the Xt direction are: a first electrode body where a wire-like electrode EG1 to serve as a negative electrode (ground) is disposed in parallel between two parallel wire-like electrodes EP1, EP2 to serve as positive electrodes; and a second electrode body where a wire-like electrode EG2 to serve as a negative electrode (ground) is disposed in parallel between two parallel wire-like electrodes EP3, EP4 to serve as positive electrodes. Further, also in FIG. 17, the electrodes EP1 to EP4, EG1, and EG2 are covered with a quartz tube as a dielectric (insulator).

In the case of the present embodiment, atmospheric pressure plasma is generated in a slot-like aperture SN1 between the electrode EP1 and the electrode EG1 and a slot-like aperture SN2 between the electrode EP2 and the electrode EG1, and in a slot-like aperture SN3 between the electrode EP3 and the electrode EG2 and a slot-like aperture SN4 between the electrode EP4 and the electrode EG2. The mist ejection unit 22A (22B) as shown in FIG. 16 is provided in alignment in the Xt direction to correspond to each of the first electrode body (EP1, EP2, EG1) and the second electrode body (EP3, EP4, EG2).

According to the present embodiment, the high-voltage pulse generation unit 40B shown in FIG. 9 is provided individually for each of the four electrodes EP1 to EP4 to serve as positive electrodes. More specifically, the electrode EP1 as a positive electrode is connected to a high-voltage pulse generation unit 40B1 that generates a high-voltage pulse voltage Vo2a in response to a primary voltage Vo1, the positive electrode EP2 is connected to a high-voltage pulse generation unit 40B2 that generates a high-voltage pulse voltage Vo2b in response to the primary voltage Vo1, the positive electrode EP3 is connected to a high-voltage pulse generation unit 40B3 that generates a high-voltage pulse voltage Vo2c in response to the primary voltage Vo1, and the positive electrode EP4 is connected to a high-voltage pulse generation unit 40B4 that generates a high-voltage pulse voltage Vo2d in response to the primary voltage Vo1.

Furthermore, according to the present embodiment, a clock generation circuit 140 is provided for generating a clock pulse CLK corresponding to the repetition frequency of the high-voltage pulse voltage. The clock generation circuit 140 can change the frequency of the generated clock pulse CLK within on the order of several hundreds of Hz to several tens of kHz in accordance with an instruction from the main control unit 100. In addition, the four high-voltage pulse generation units 40B1 to 40B4 respectively output high-voltage pulse voltages Vo2a to Vo2d in response to the clock pulse CLK.

According to the present embodiment, the clock pulse CLK is supplied to a series connection of three delay circuits 142A, 142B, 142C with the same delay time ΔTd, thereby delaying the clock pulse applied to the high-voltage pulse generation unit 40B2 by the ΔTd with respect to the original clock pulse CLK, delaying the clock pulse applied to the high-voltage pulse generator 40B3 by time 2·ΔTd with respect to the original clock pulse CLK, and delaying the clock pulse applied to the high-voltage pulse generator 40B4 by time 3·ΔTd with respect to the original clock pulse CLK.

The delay time ΔTd is set to ¼ or less of the period of the original clock pulse CLK. As a result, atmospheric pressure plasma is generated at time intervals in the order of the apertures SN1, SB2, SN3, SN4 (the order in the conveying direction of the substrate FS).

In addition, four clock pulses that are individually capable of undergoing frequency change may be generated from the clock generation circuit 140, and the four clock pulses may be applied respectively to the four high-voltage pulse generation units 40B1 to 40B4 to adjust the generation condition (film formation condition) of atmospheric pressure plasma generated in each of the apertures SN1, SB2, SN3, SN4 by changing the frequency of each clock pulse. Furthermore, it is possible to adjust the generation condition of atmospheric pressure plasma (film formation condition) by individually changing the primary voltage Vo1 applied to each of the four high-voltage pulse generation units 40B1 to 40B4.

### Modified Example 1 of Electrode Structure

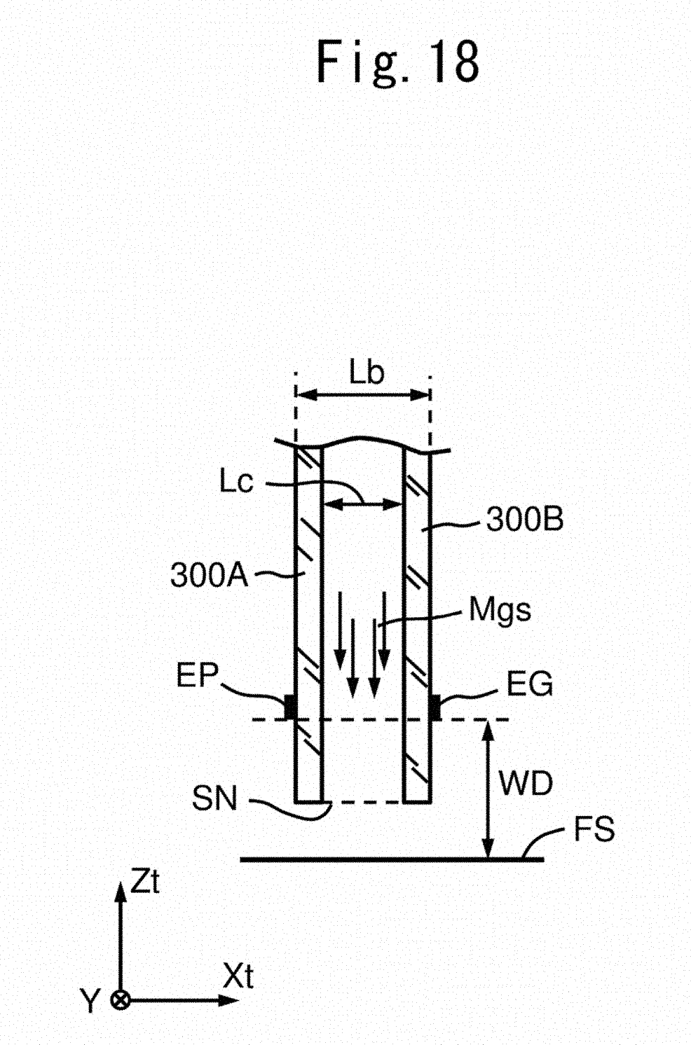

FIG. 18 is a diagram illustrating a first modified example of the electrode structure provided at the tip of the mist ejection unit 22. In the mist ejection unit 22 according to the present modified example, two parallel flat plates 300A, 300B made of quartz extending in the Y direction are opposed so as to be parallel at an interval Lc in the Xt direction. Mist gas Mgs is allowed to flow in the −Zt direction in the space with the interval Lc formed by the parallel flat plates 300A, 300B, and the mist gas Mgs is injected from a slot-like aperture SN formed at the end surfaces of the parallel flat plates 300A, 300B on the −Zt side toward a substrate FS.

Openings on both ends of the parallel flat plates 300A, 300B in the Y direction are covered with quartz plates. Metallic thin-plate electrodes EP, EG extending in the Y direction are formed on the outer side surfaces of the parallel flat plates 300A, 300B so as to be parallel to each other in the Y·Xt plane and in the Xt·Zt plane. The width of the electrodes EP, EG in the Zt direction is set to be relatively narrow so that atmospheric pressure plasma in a non-thermal equilibrium state is generated in a stable manner.

In accordance with the exemplification according to the previous respective embodiments, the electrode interval Lb can be set to about 5 mm when the thickness of the parallel flat plate 300A, 300B is about 0.7 mm, and when the interval Lc inside the parallel flat plates 300A, 300B is about 3.6 mm. According to this modified example, the distance of the aperture SN through which the mist gas Mgs is injected, from the substrate FS, can be made smaller than the working distance WD of the electrodes EP, EG from the substrate FS, and the mist gas Mgs can be thus injected intensively onto the substrate FS. In addition, a suction duct port (suction slot), not shown, for collecting the mist gas Mgs injected from the aperture SN may be provided near the aperture SN on the outside (−Xt side) of the parallel flat plate 300A, or the outside (+Xt side) of the parallel flat plate 300B, thereby regulating the flow of the mist gas Mgs injected onto the substrate FS.

### Modified Example 2 of Electrode Structure

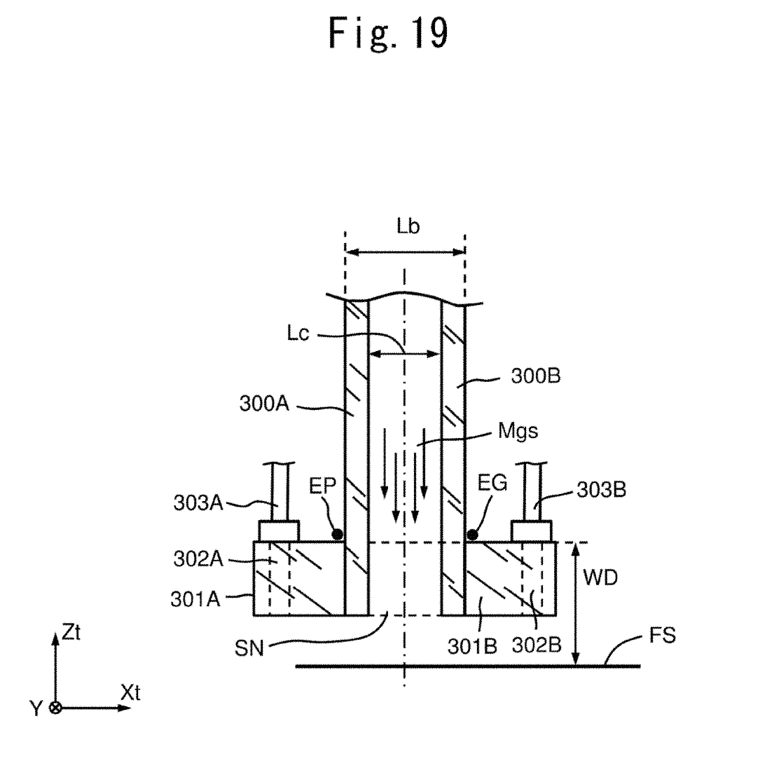

FIG. 19 is a diagram illustrating a second modified example of the electrode structure provided at the tip of the mist ejection unit 22. In this figure, rectangular column members 301A and 301B of the same size made of quartz extending in the Y direction are attached to the configuration of FIG. 18, outside ends of the parallel flat plates 300A, 300B on the −Zt side thereof. The rectangular column members 301A, 301B increase the rigidity of the mist ejection unit (nozzle) 22 provided by the two parallel flat plates 300A, 300B, and increase the parallelism of the parallel flat plates 300A, 300B.

Furthermore, in the case of this example, the electrodes EP, EG are adapted to have conductive wires that are circular in cross-section as shown in the previous embodiments. The wire-like electrode EP is disposed linearly along an apex angle part (a ridge line extending in the Y direction) formed by the outer side surface (the surface on the −Xt side) of the parallel flat plate 300A and the upper surface (the surface on the +Zt side) of the rectangular column member 301A, whereas the wire-like electrode EG is disposed linearly along an apex angle part (a ridge line extending in the Y direction) formed by the outer side surface (the surface on the +Xt side) of the parallel flat plate 300B and the upper surface (the surface on the +Zt side) of the rectangular column member 301B.

In addition, in order to collect the mist gas Mgs injected from the aperture SN, suction duct ports (suction holes) 302A, 302B for providing a negative pressure in the space between the lower surface of each of the rectangular column members 301A, 301B and the substrate FS can be provided on the rectangular column members 301A, 301B. The suction duct ports (suction holes) 302A, 302B are connected to exhaust pipes 303A, 303B, respectively. With this configuration, the flow of the mist gas Mgs injected onto the substrate FS can be adjusted by adjusting the suction flow rate of the suction duct ports (suction holes) 302A, 302B depending on the ejection flow rate of the mist gas Mgs from the aperture SN. It is to be noted that in FIG. 19, the suction duct ports (suction holes) 302A, 302B may extend in a slot form in the Y direction, or may have a plurality of circular openings arranged at predetermined intervals in the Y direction.

### Modified Example 3 of Electrode Structure

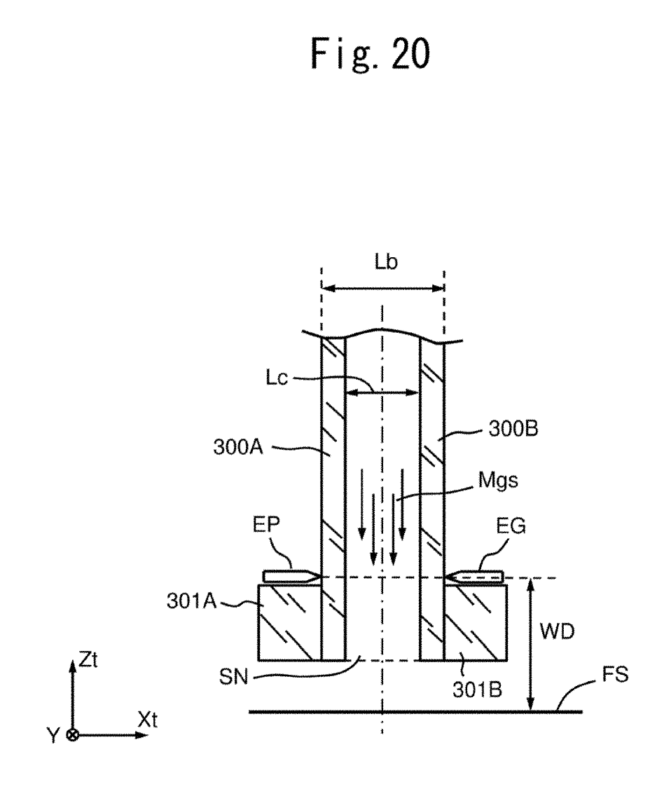

FIG. 20 is a diagram illustrating a third modified example of the electrode structure provided at the tip of the mist ejection unit 22. In this figure, as with the configuration in FIG. 19, rectangular column members 301A and 301B of the same size made of quartz extending in the Y direction are attached outside ends of the parallel flat plates 300A, 300B on the −Zt side thereof. The rectangular column members 301A, 301B increase the rigidity of the mist ejection unit (nozzle) 22 provided by the two parallel flat plates 300A, 300B, and increase the parallelism of the parallel flat plates 300A, 300B. In addition, although not shown in FIG. 20, the rectangular column members 301A and 301B may be provided with suction duct ports (suction holes) 302A, 302B as shown in FIG. 19.

Each of the electrodes EP, EG according to the present example is formed to have a constant thickness in the Zt direction and extend in a plate form in the Y direction parallel to the Y-Xt plane. Of ends of the electrodes EP, EG in the Xt direction, the ends opposed to each other are formed in the form of a knife edge linearly extending in the Y direction. The electrode EP according to the present example is fixed to the upper surface of the rectangular column member 301A so that the leading end in the shape of a knife edge on the +Xt side is brought in abutment with the outer side surface of the parallel flat plate 300A, whereas the electrode EG is fixed to the upper surface of the rectangular column member 301B so that the leading end in the shape of a knife edge on the −Xt side is brought in abutment with the outer side surface of the parallel flat plate 300B.

Therefore, the closest parts of the pair of electrodes EP, EG serve as knife edge-like leading ends opposed parallel at the interval Lb in the Xt direction, that is, thin-line ends extending linearly in the Y direction.

### Modified Example 1 of Arrangement of Mist Ejection Unit

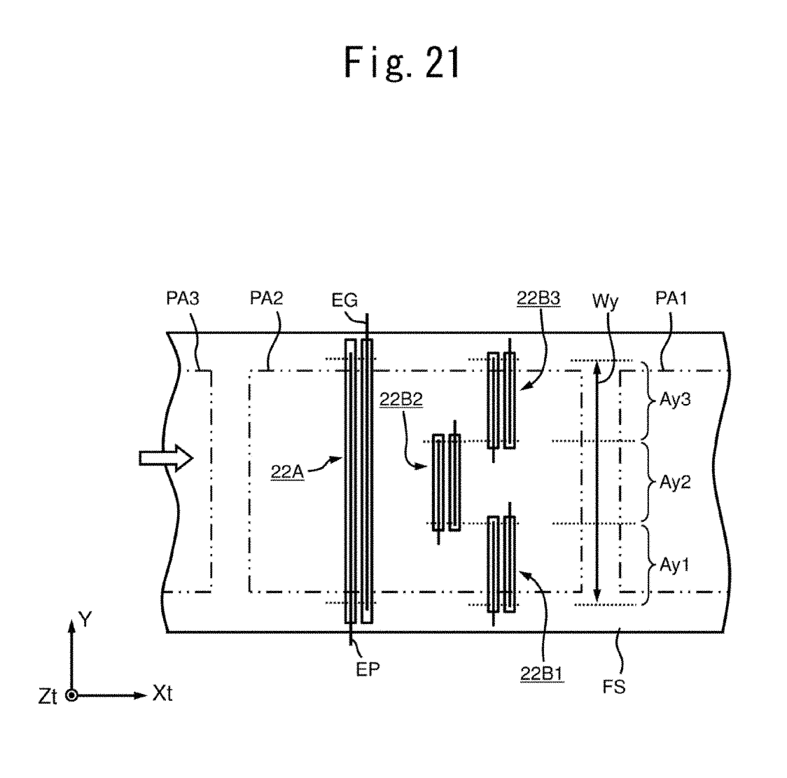

FIG. 21 shows a first modified example of the arrangement of the tip (and electrodes 24) of the mist ejection unit 22 in the Xt-Y plane. In FIG. 21, a sheet-like substrate FS is adapted to be held in a planar shape and conveyed in the +Xt direction as shown in FIG. 5, and on the substrate FS, multiple rectangular device formation regions PA1, PA2, PA3 are set in the longitudinal direction with a predetermined gap therebetween. The tip (a slot-like opening SN, and an electrode 24A and an electrode 24B) of a first mist ejection unit 22A is provided to extend in the Y direction, so as to eject a mist gas Mgs assisted by atmospheric pressure plasma over the entire processing width Wy that covers the widths of the foregoing device formation regions PA1, PA2, PA3 in the Y direction. Three second mist ejection units 22B1, 22B2, 22B3 that have apertures SN comparable to the dimension in the Y direction for each region obtained by dividing the region of the processing width Wy on the substrate FS substantially into three equal parts in the Y direction are arranged downstream in the conveying direction of the substrate FS with respect to the tip of the first mist ejection unit 22A.

The respective tips of the first mist ejection unit 22A and the second mist ejection units 22B1, 22B2, 22B3 are configured in the same fashion as those in FIGS. 6 and 7, respectively. Therefore, the width Lc of the aperture SN at the tip in the Xt direction and the interval Lb between the electrodes EP, EG of each mist ejection unit are set equally among all of the first mist ejection unit 22A and second mist ejection units 22B1, 22B2, 22B3, which are adapted to differ only in the length of the tip in the Y direction. In addition, the tip of the second mist ejection unit 22B2 is displaced upstream (on the side close to the first mist ejection unit 22A) with respect to the respective tips of the second mist ejection units 22B1, 22B3. The first mist ejection unit 22A forms a film of specific substance over the entire processing width Wy on the substrate FS by a mist CVD method or a mist deposition method, and the second mist ejection unit 22B2 forms, by a mist CVD method or a mist deposition method, a film of specific substance in a central region Ay2 of regions obtained by dividing the processing width Wy into three. Likewise, the second mist ejection units 22B1, 22B3 form, by a mist CVD method or a mist deposition method, films of specific substances respectively on both end regions Ay1, Ay3 of the regions obtained by dividing the processing width Wy into three.

According to this example, when the layer thickness of a thin film of a specific substance formed with the use of the first mist ejection unit 22A has unevenness in the width direction (Y direction) of the substrate FS, for example, when the thicknesses of thin films formed in the both end regions Ay1, Ay3 are smaller than the thickness of a thin film formed in the central region Ay2, additional film formation can be performed individually by the second mist ejection units 22B1, 22B3 corresponding respectively to the both end regions Ay1, Ay3, thereby making film thickness unevenness correction for improving the film thickness uniformity in the width direction of the substrate FS.

Therefore, when it is necessary to correct further finely the unevenness of the film thickness of a formed thin film in the width direction of the substrate FS, the second mist ejection units 22 maybe divided into four or more in the width direction of the substrate FS and arranged such that film formation by a mist CVD method or a mist deposition method can be performed individually. In addition, in the configuration shown in FIG. 21 according to this example, the respective tips of the three second mist ejection units 22B1, 22B2, 22B3 are arranged downstream of the first mist ejection unit 22A, so as to cover the processing width Wy of the substrate FS, thus making it possible to increase the film formation rate in the same manner as in the previous configurations of FIGS. 5, 13, and 14. Furthermore, when a plurality of first mist ejection units 22A is arranged in the conveying direction (Xt direction) of the substrate FS, it is possible to further increase the film formation rate while correcting the film thickness unevenness.

Further, feedback control system can be also provided which measures the film thickness of a specific substance deposited on the substrate FS after the film formation at each of multiple points in the width direction of the substrate FS with the use of a film thickness measurement machine, on the basis of the measurement values, figures out the tendency and extent of film thickness unevenness in the width direction of the substrate FS, and in order to correct the unevenness, dynamically adjusts the film formation condition (the ejection flow rate, temperature, or concentration of mist gas Mgs, or a pulse voltage Vo2 to be applied to the electrode part 24, the frequency thereof, etc.) provided by each of the second mist ejection units 22B1, 22B2, 22B3. In this case, the control of thickness unevenness of the film formed on the substrate FS is automated. In addition, a movable mechanism may be provided which translates or rotates (inclines) the respective tips (the apertures SN and the electrodes 24) of the second mist ejection units 22B1, 22B2, 22B3 in a plane parallel to the surface of the substrate FS (in the Y-Xt plane), and the movable mechanism may be controlled by a motor driven in accordance with an instruction from the feedback control system.

### Modified Example 2 of Arrangement of Mist Ejection Unit

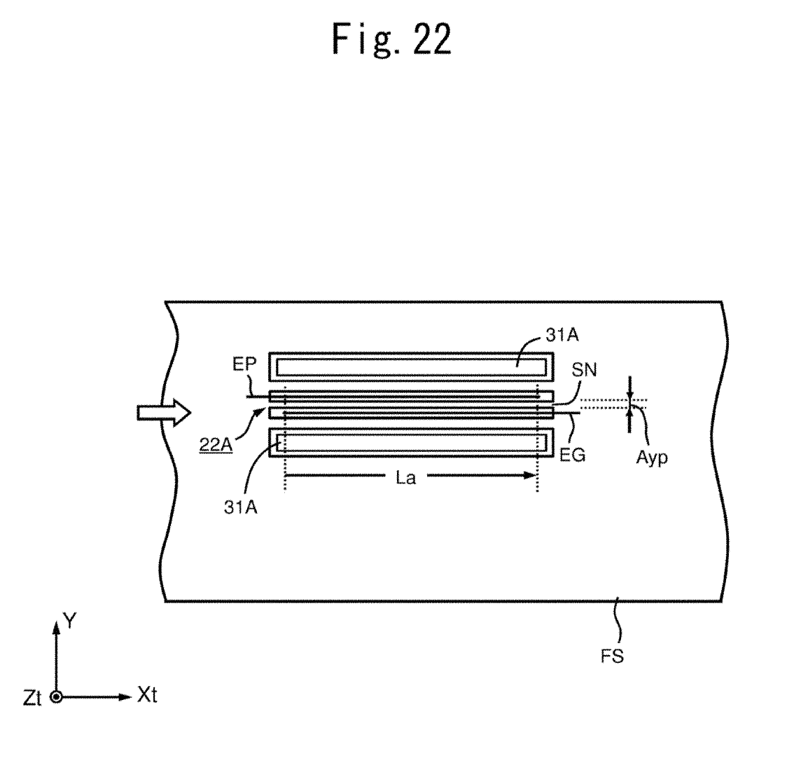

FIG. 22 shows a second modified example of the arrangement of the tip (slot-like aperture SN, and electrode 24A and electrode 24B) of the mist ejection unit 22A in the Xt-Y plane. In FIG. 22, the tip (the aperture SN and the electrode 24A (24B)) of the same first mist ejection unit 22A as in FIG. 21 is rotated by 90 degrees around the axis parallel to the Zt axis (perpendicular to the Y-Xt plane) from the state of FIG. 21. Furthermore, according to this example, a gas collection duct 31A as shown in FIG. 13 is provided on both sides of the tip of the mist ejection unit 22A in the Y direction.

In the arrangement of FIG. 22, a substrate FS is moved in the +Xt direction along the Y-Xt plane, but as viewed in the XYZ coordinate system, the substrate FS inclined at about 45 degrees with respect to the XY plane is conveyed in the longitudinal direction. Therefore, the tip of the mist ejection unit 22A in FIG. 22 is disposed so that the longitudinal direction of the slot-like aperture SN is inclined by about 45 degrees with respect to the XY plane.

When the longitudinal direction of the aperture SN of the mist ejection unit 22A is aligned with the direction in accordance with the conveying direction of the substrate FS in this manner, the region of film formation on the substrate FS by receiving the injection of a mist gas Mgs assisted by atmospheric pressure plasma is restricted to a region Ayp where the width in the Y direction is comparable to the interval Lb between the electrodes EP, EG. However, in the region Ayp, the film formation rate is improved because the time period of continuing to receive the injection of the mist gas Mgs is made longer depending on the length La of the opening SN in the longitudinal direction.

According to the present example, when the region to be subjected to film formation may be a partial region where the width in the Y direction is restricted like the region Ayp extending in a stripe form in the Xt direction, it is possible to increase the film formation rate.

Further, in the configuration of FIG. 22 as well, as in FIG. 21 shown previously, the second mist ejection unit 22B for correction, for adjusting the film thickness, may be arranged downstream of the mist ejection unit 22A in the conveying direction of the substrate FS. In addition, providing a drive mechanism that allows the tip of the mist ejection unit 22A to rotate (incline) about an axis parallel to the Zt axis can change the width of the region Ayp in the Y direction, and change the film formation rate.

### MODIFIED EXAMPLE OF STRUCTURE OF TIP OF MIST EJECTION UNIT

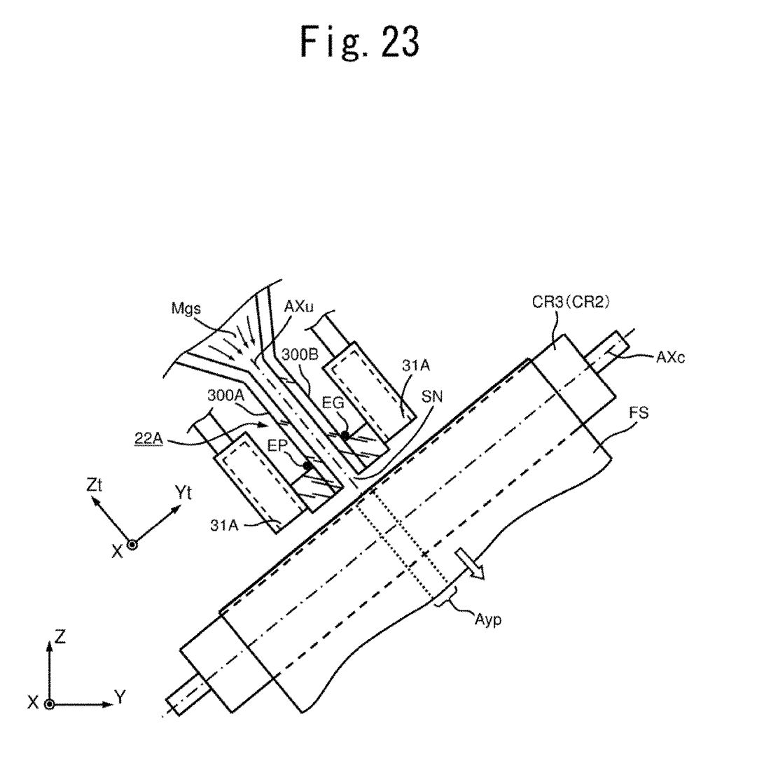

FIG. 23 shows a modified example of the structure of the tip (slot-like aperture SN and electrode portion 24A (24B)) of the mist ejection unit 22A. In FIG. 23, the tip (aperture SN and electrodes EP, EG) of the first mist ejection unit 22A shown in FIG. 19 is disposed with respect to the substrate FS such that the longitudinal direction of the aperture SN is the same as the conveying direction of the substrate FS as is the case with FIG. 22, and a gas collection duct 31A is provided on both sides of the tip of the first mist ejection unit 22A. Further, the first mist ejection unit 22A and the gas collection duct 31A are inclined in the range of 45°±15° in the YZ plane, rather than in the XZ plane of the XYZ coordinate system, and rollers CR2, CR3 for conveyance are arranged such that the substrate FS is inclined in the width direction. More specifically, the rollers CR2, CR3 are placed in such a manner that the height positions of the two rollers CR2, CR3 shown in FIG. 5 in the Z direction are aligned to incline each rotation axis AXc in the range of 45°±15° from the Y axis within the YZ plane. It is to be noted that one of the two gas collection ducts 31A shown in FIG. 23, located in the −Z direction (or −Yt direction) with respect to the aperture SN at the tip of the first mist ejection unit 22A, may be omitted.

In this way, the residence time of the mist gas Mgs injected from the aperture SN at the tip of the first mist ejection unit 22A onto the substrate FS, is made slightly longer on the surface of the substrate FS mainly by the action of the upper gas collection duct 31A (located in the +Z direction or the +Yt direction with respect to the aperture SN of the first mist ejection unit 22A), thereby suppressing the decrease in film formation rate. Also in this example, the first mist ejection unit 22A and the gas collection duct 31A can be configured to be rotatable around the axis AXu parallel to the Zt axis through the center of the aperture SN, and configured to be movable in parallel in the X-Yt plane. Thus, it is possible to change the position or width in the Yt direction, of the region Ayp to be subjected to film formation in a stripe form on the substrate FS, or change the film formation rate.

### Example 1

Film formation was performed onto the substrate FS by a mist CVD method with the use of the thin film manufacturing device 1 according to the first embodiment. An m-plane sapphire substrate was used for the substrate FS. For the precursor LQ, a zinc chloride aqueous solution (ZnCl₂) was used, the solution concentration was 0.1 mol/L, and the solution amount was 150 ml.

The application of a voltage to the ultrasonic vibrator 206 causes the ultrasonic transducer 206 to vibrate at 2.4 MHz to atomize the solution. For the transport of the mist, Ar gas was used, and introduced at a flow rate of 1 L/min from the gas introduction pipe 215 into the thin film manufacturing device 1. The heating temperature for the heater 23 located in the mist transport path 212 was set to 190° C., thereby heating the path of the sprayed mist.

In addition, heating at 190° C. was performed by the heater unit 27 from the back side of the substrate FS. The interval Lb between the electrode 24A and the electrode 24B was adjusted to 5 mm, and the distance WD between the electrode 24A and the electrode 24B and the substrate FS was adjusted to 7 mm. Titanium (Ti) wires were used for the electrode EP and the electrode EG, and covered with quartz tubes of 3 mm in outer diameter and 1.6 mm in inner diameter to serve respectively as a dielectric Cp and a dielectric Cg. Therefore, the width Lc was 2 mm as the gap between the dielectric Cp and the dielectric Cg.

As a plasma generation condition, the high-voltage pulse power supply unit 40 shown in FIG. 9 was used to set the frequency of 1 kHz and the primary voltage Vo1=100 V. The values actually measured by an oscilloscope were: output pulse voltage Vo2 (maximum value) of 16.4 kV; discharge current (maximum value) of 443.0 mA; energy per pulse of 0.221 mJ/pulse; and power of 221 mW (=mJ/s). Under these conditions, the mist passing through plasma generated between the electrodes was delivered to the substrate FS.

The film formation time was 60 minutes, and the film thickness was about 130 nm, and the film formation rate was thus about 2.1 nm/min.

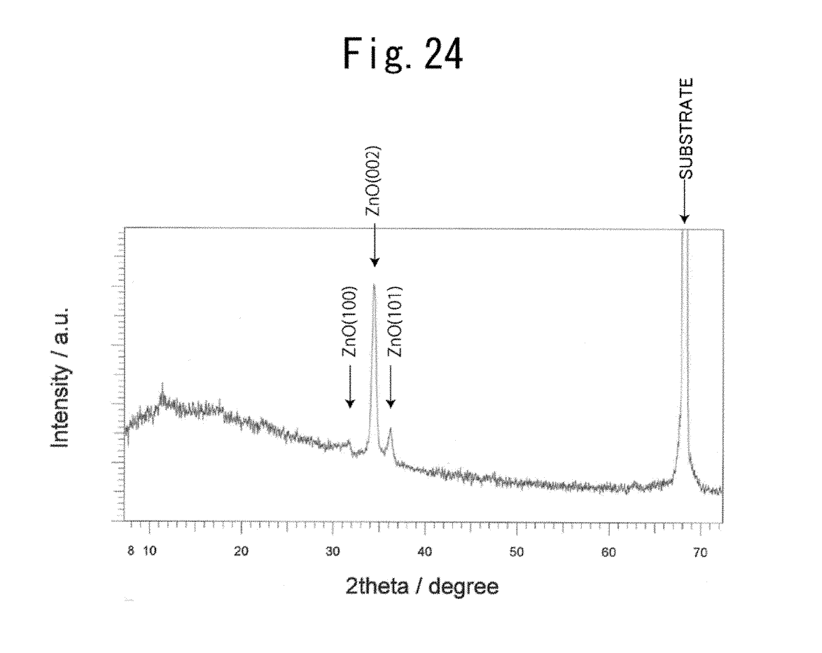

FIG. 24 is a diagram showing the result of analysis by XRD for a part just above the electrode in the film formation obtained according to Example 1. The XRD measurement of the part just above the electrode has confirmed only diffraction on ZnO, and above all, diffraction on ZnO (002) has been found to be strong, suggesting a strong tendency of C axis orientation with respect to the substrate FS.

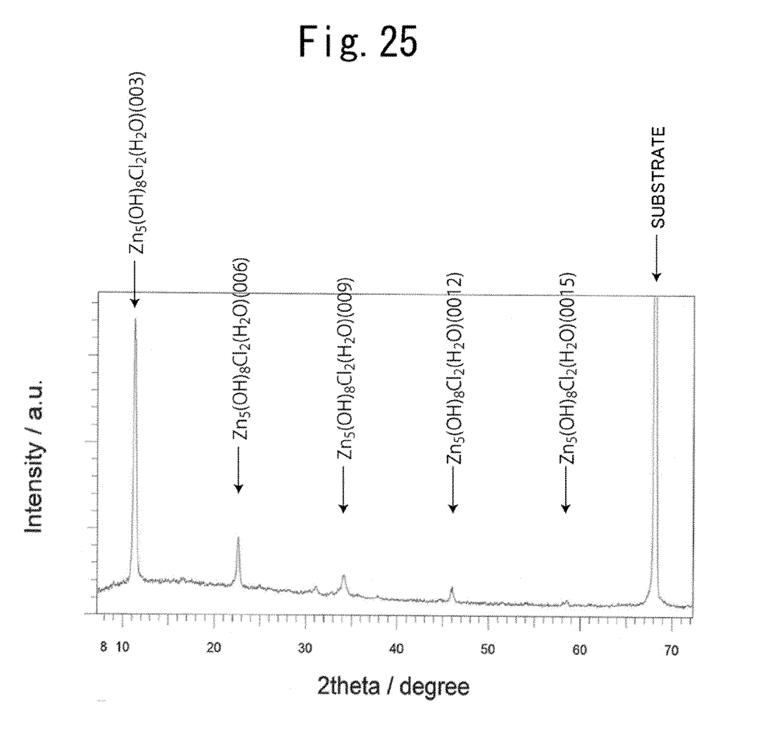

FIG. 25 is a diagram showing the result of analysis by XRD for a part away from the part just above the electrode in the film formation obtained according to Example 1. This figure is the result of analysis at a location far away (about 1.5 cm) from the part just above the electrode, and it can be said that any zinc oxide has failed to be formed, due to the observation of only diffraction derived from a hydrate which seems Zn₅(OH₈)Cl₂(H₂O).

### Comparative Example 1

Film formation was attempted onto the substrate FS by a mist CVD method with the use of the thin film manufacturing device 1 according to the first embodiment. In that regard, no voltage was applied to the electrodes 24A and the electrode 24B. The other conditions are the same as those in Example 1.

As a result, no plasma was generated between the electrodes, and the mist passing between the electrodes acted on the substrate FS without being affected by any plasma.

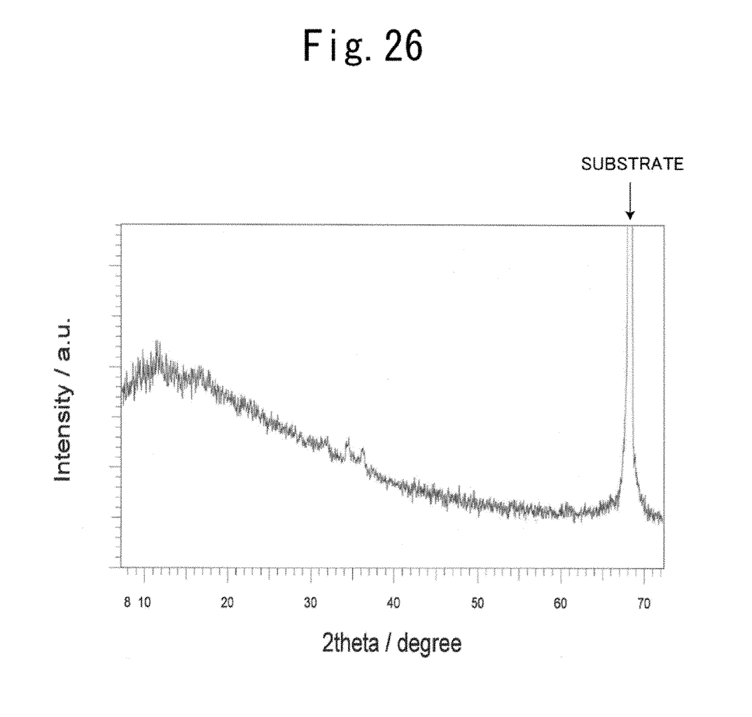

FIG. 26 is a diagram showing the result of analysis by XRD for a part just above the electrode, of the film obtained according to Comparative Example 1. The adhesion of the film can be hardly confirmed on the part just above the electrode. Further, ZnO film formation was failed to be confirmed even at a location away from the part just above the electrode. From the foregoing results, it has been demonstrated that plasma assistance is required for the formation of a ZnO film at a substrate temperature of 200° C. or lower.

### Example 2

Film formation was performed onto the substrate FS by a mist deposition method with the use of the thin film manufacturing device 1 according to the second embodiment. Quartz glass was used for the substrate FS. An aqueous dispersion (Nano Tek (registered trademark) Slurry: from CI Kasei Co., Ltd.) including ITO fine particles was used for the precursor LQ. The ITO fine particles were 10 to 50 nm in particle size, and 30 nm in average particle diameter, and the concentration of the metal oxide fine particles in the aqueous dispersion was 15 wt %.

The application of a voltage to the ultrasonic vibrator 206 causes the ultrasonic transducer 206 to vibrate at 2.4 MHz to atomize the solution, and the atomized mist was carried by causing Ar as a carrier gas to flow at 10 L/min with the use of nitrogen as a carrier gas.

The interval Lb between the electrode 24A and the electrode 24B was adjusted to 5 mm, and the distance WD between the electrode 24A and the electrode 24B and the substrate FS was adjusted to 7 mm. Titanium (Ti) wires were used for the electrode EP and the electrode EG, and covered with quartz tubes of 3 mm in outer diameter and 1.6 mm in inner diameter to serve respectively as a dielectric Cp and a dielectric Cg. Therefore, the width Lc was 2 mm as the gap between the dielectric Cp and the dielectric Cg.

As a plasma generation condition, the high-voltage pulse power supply unit 40 shown in FIG. 9 was used to set the frequency of 1 kHz and the primary voltage Vo1=80 V. The values actually measured by an oscilloscope were: output pulse voltage Vo2 (maximum value) of 13.6 kV; discharge current (maximum value) of 347.5 mA; energy per pulse of 0.160 mJ/pulse; and power of 160 mW (=mJ/s). Under these conditions, the mist passing through plasma generated between the electrodes was delivered to the substrate FS.

Without any heating during film formation, the film formation was performed so that the mist was sprayed perpendicularly to the substrate FS, with the substrate FS inclined at 45 degrees with respect to the horizontal direction. The film thickness of the thin film obtained was measured with a step/surface roughness/fine shape measurement device (P-16+: from KLA Tencor), and the calculation of the film formation rate resulted in a film formation rate of 90 nm/min.

### Comparative Example 2

In the same way as in Example 2, film formation was performed onto the substrate FS by a mist deposition method with the use of the thin film manufacturing device 1 according to the second embodiment. In that regard, no voltage was applied to the electrodes 24A and the electrode 24B. The other conditions are the same as those in Example 2.

Consideration will be given to the film formation results of Example 2 and Comparative Example 2. The film formation rate in Example 2 was 90 nm/min, whereas the film formation rate in Comparative Example 2 was 70 nm/min, and it has been thus determined that the film formation rate is improved by plasma assistance.

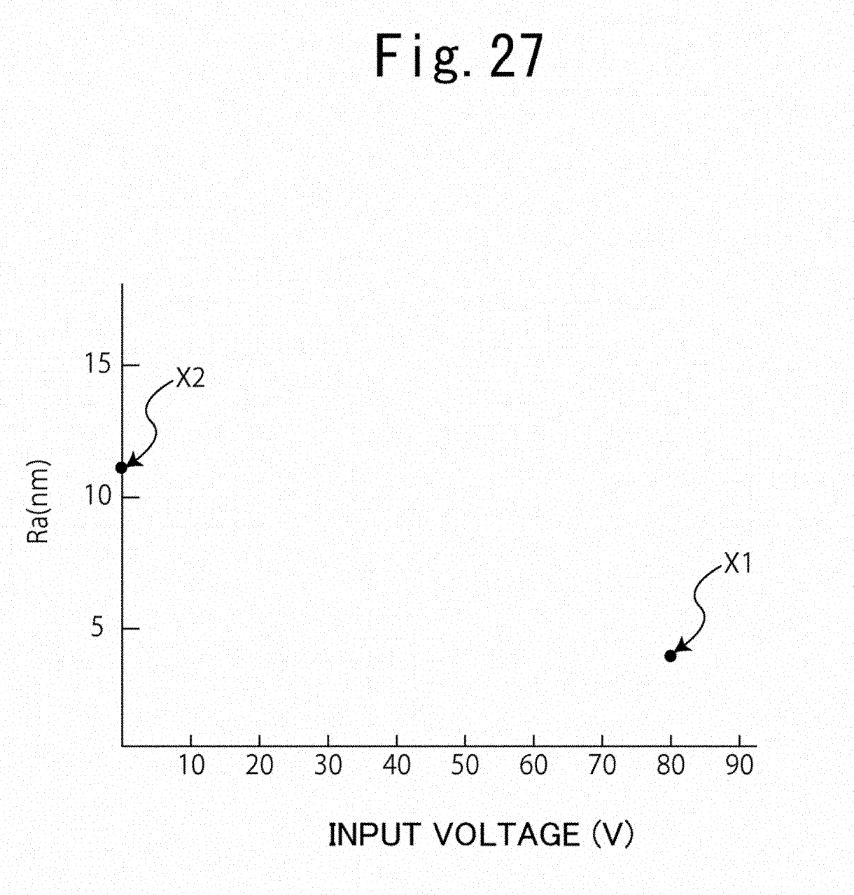

FIG. 27 is a diagram showing measurement values of surface roughness for the thin films according to Example 2 and Comparative Example 2. The surface roughness was measured with the use of a scanning probe microscope (from JEOL Ltd.). As a unit of surface roughness, arithmetic mean roughness (Ra) was used. “X1” indicates the surface roughness in Example 2. The surface roughness was 4.5 nm. “X2” indicates the surface roughness in Comparative Example 2. The surface roughness was 11 nm. As for the surface roughness, it has been determined that plasma assistance makes the surface roughness equal to or less than half.

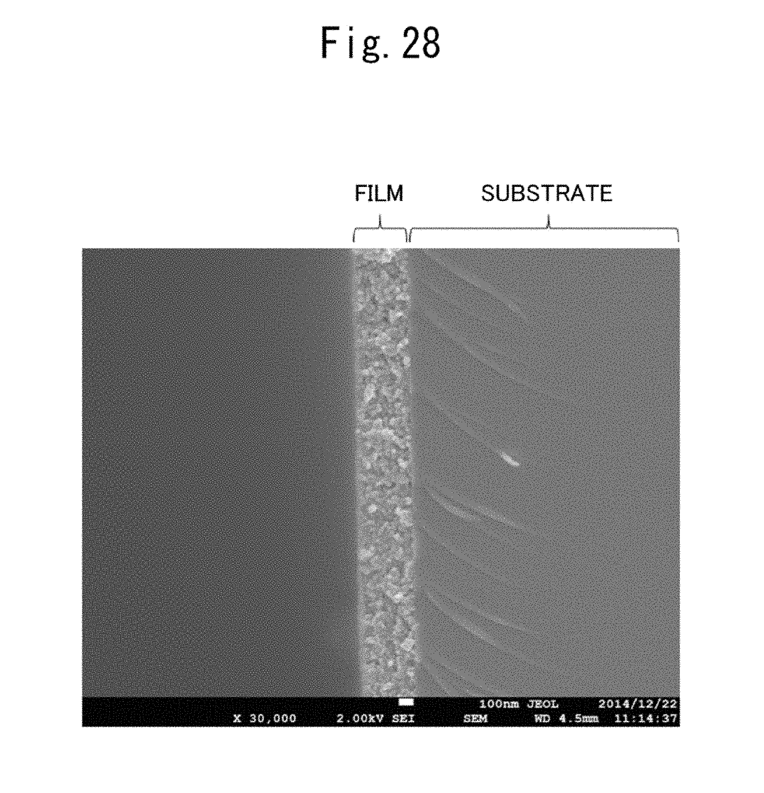

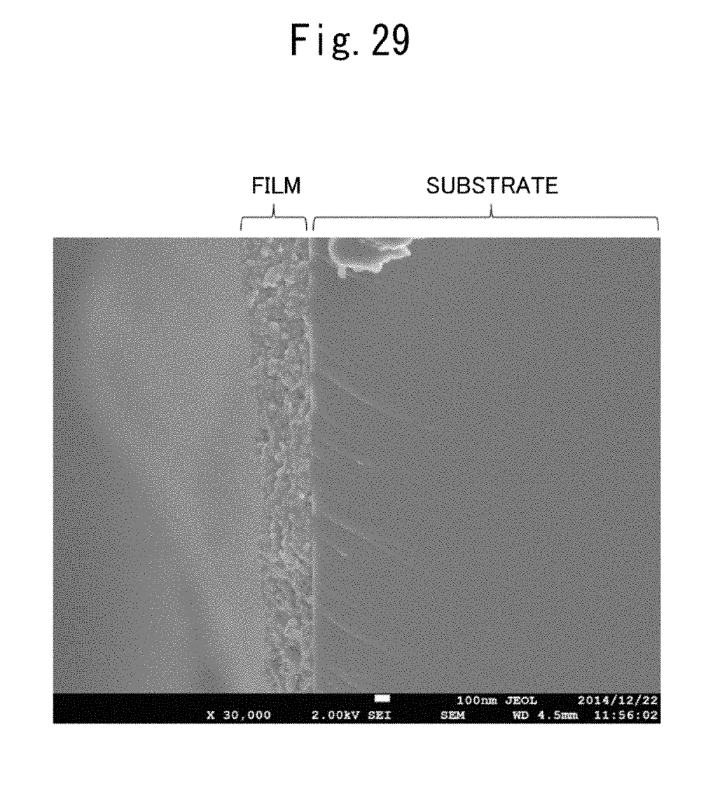

FIG. 28 is an SEM image of the film obtained according to Example 2, and FIG. 29 is a SEM image of the thin film obtained according to Comparative Example 2. As also shown in FIGS. 28 and 29, it is determined that that the surface of the thin film obtained according to Example 2 is smoother than the surface of the thin film obtained according to Comparative Example 2.

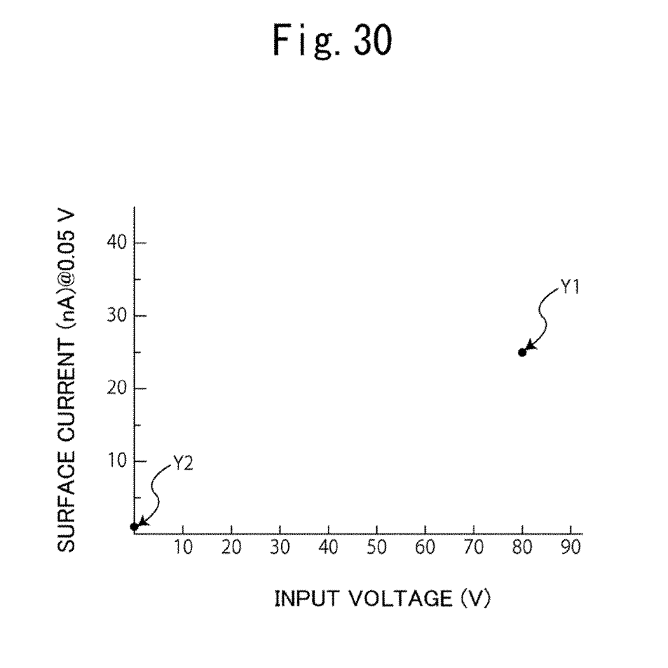

FIG. 30 is a diagram showing measurement values of surface current for thin films according to Example 2 and Comparative Example 2. The figure shows the results of measuring the surface currents by applying a voltage of 0.05V to the samples. “Y1” is the surface current in Example 2. The surface current was 27 nA. “Y2” is the surface current in Comparative Example 2. The surface current was 2 nA. As for the surface current, it has been successfully confirmed that plasma assistance improves the conductivity of the sample.

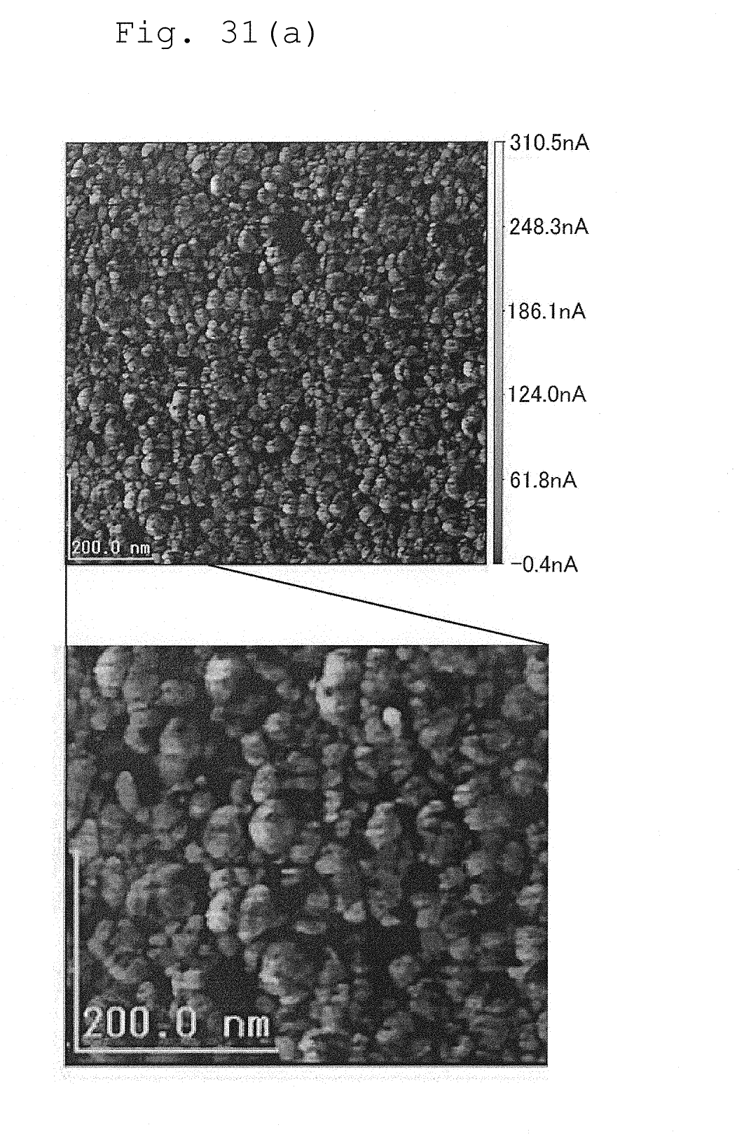

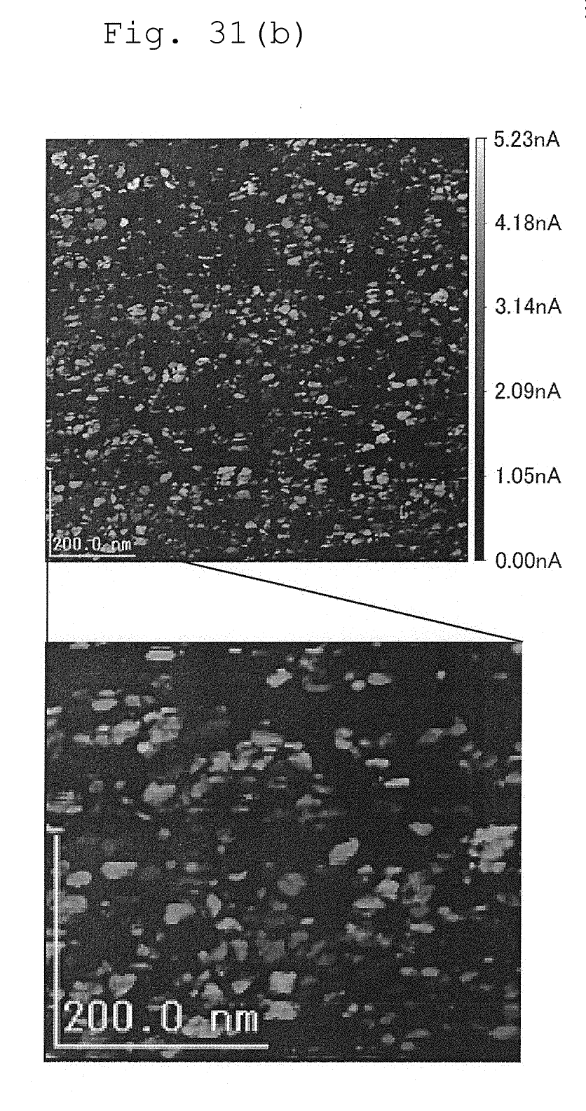

FIG. 31(a) and FIG. 31(b) are diagrams showing the mapping results of surface potentials in Example 2 and Comparative Example 2. FIG. 31(a) is the surface potential mapping for the film formed according to Example 2, and a partial enlargement of the upper diagram of FIG. 31(a) corresponds to the lower diagram of FIG. 31(a). FIG. 31(b) is the surface potential mapping for the film formed according to Comparative Example 2, and a partial enlargement of the upper diagram of FIG. 31(b) corresponds to the lower diagram of FIG. 31(b).

Referring to FIG. 31(b), when plasma is not used, there are many black portions as compared with the case of using the plasma as shown in FIG. 31(a), and the portions are poor in conductivity, and it has been thus determined that the in-plane electrical conduction is blocked. On the other hand, it has been determined that the film obtained when the plasma is used as shown in FIG. 31(a) has high conductivity in the entire in-plane region. Also as for the particle size in the in-plane direction, it has been determined that crystal grains undergo increase in size when plasma is used.

### Example 3

In the same way as in Example 2, film formation was performed onto the substrate FS by a mist deposition method with the use of the thin film manufacturing device 1 according to the second embodiment. The conditions excluding the following plasma generation conditions and film formation conditions are the same as those in Example 2.

As the film formation conditions, with the substrate FS inclined with respect to the horizontal plane, and the substrate FS inclined at 45 degrees with respect to a plane perpendicular to the spraying direction of the mist, the mist was sprayed. The spraying was carried out at room temperature, and the substrate FS was not heated. As the plasma generation conditions, electrodes EP and EG using titanium (Ti) wires were used, and covered respectively with a dielectric Cp and a dielectric Cg using silicon oxide (SiO₂). Further, with the use of the high-voltage pulse power supply unit 40 shown in FIG. 9, a voltage was applied so as to obtain an inter-electrode voltage Vo2 of 19 kV. In that regard, the frequency was varied between 1 kHz and 10 kHz, thereby providing multiple samples.

After the mist spraying, the samples were placed in a heating furnace, and heated at 200° C. The heating was carried out under an inert gas (N2) atmosphere for 10 minutes. Thereafter, the surface of the dried ITO film was irradiated with ultraviolet rays (wavelength: 185 nm mixed with 254 nm) to remove impurities, and subsequently, the mist was sprayed for 1 minute onto the ITO film with the impurities removed from the surface with the use of the thin film manufacturing device 1 under the same conditions as described above. As just described, since the film surface is rendered hydrophilic by removing impurities through the irradiation with ultraviolet rays, the mist is more likely to adhere to the film surface when the mist is subsequently sprayed. Therefore, in the case of forming a thin film by performing the mist spraying more than once, the ultraviolet irradiation step is effective. Thereafter, the same heating, ultraviolet irradiation, and mist spraying were repeated. As a result of repeating the series of steps three times, a sample sprayed with mist three times was obtained, and the resistivity of the obtained sample was measured.

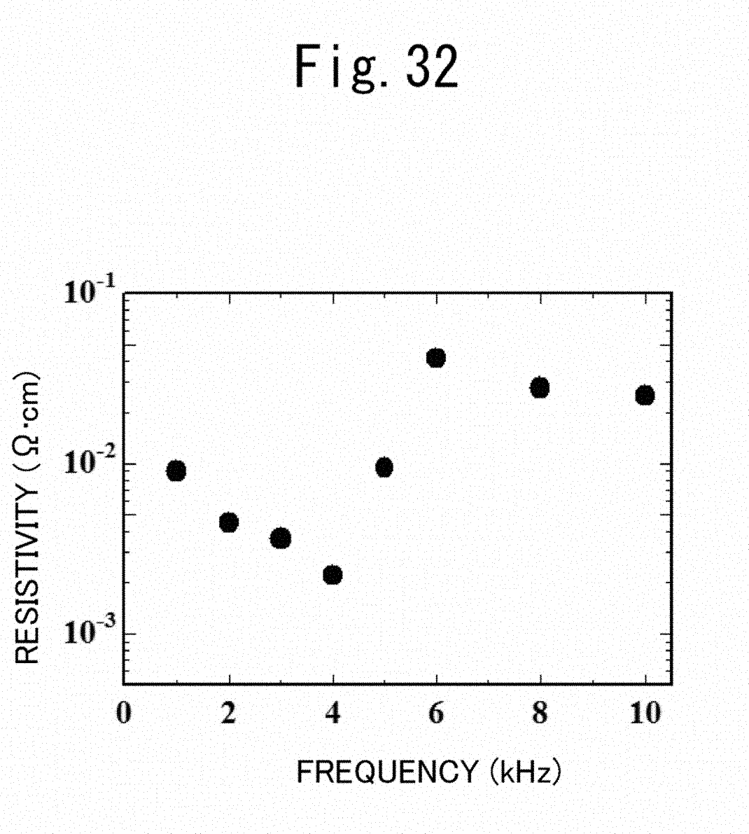

FIG. 32 is a diagram showing the resistivity of the thin film according to Example 3. As the frequency is increased up to 4 kHz, the resistivity tends to decrease, and shows the minimum resistivity at 4 kHz. Then, as the frequency is increased, the resistivity turns to an upward trend, and shows the maximum resistivity at 6 kHz. After 6 kHz, the resistance value undergoes an increase by one or more digits.

The reason for this result is believed to be that the influence of the ion wind generated between the electrodes due to the frequency increase was increased, thereby disturbing the mist reaching on the substrate FS, and thus decreasing the uniformity. Alternatively, it is believed that the ITO particles aggregate to form large secondary particles as the particles pass through the high-energy plasma generated by the frequency increase, thereby decreasing the degree of denseness of the particle film formed on the substrate FS.

In the case of using the obtained thin film as a semiconductor device for a liquid crystal display or a solar cell, the resistance value is preferably low. Therefore, when a voltage is applied at a frequency of 1 kHz or more and less than 6 kHz, a more preferred thin film can be obtained. It is to be noted that the frequency for voltage application is more preferably 2 kHz or more and 5 kHz or less. In addition, the voltage applied to the electrodes is desirably 19 kV (electric field: 3.8×10⁶ V/m) or more.

### REFERENCE SIGNS LIST

1 thin film manufacturing device
10 first chamber
10A, 10B air-sealing part
12 second chamber
12A, 12B air-sealing part
12C duct
20 mist generation tank
20A, 20B mist generation unit
21A duct
22, 22A, 22B, 22C, 22D mist ejection unit
23, 23A heater
24A, 24B electrode
25A top board
27, 27A, 27B, 27C, 27D heater unit
28 temperature control unit
30 exhaust control unit
30A duct
31A, 31B, 31C, 31D gas collection duct
40 high-voltage pulse power supply unit
40A variable direct-current power supply
40B, 40B1, 40B2, 40B3, 40B4 high-voltage pulse generation unit
40Ba pulse generation circuit section
40Bb boosting circuit section
51 drying/temperature control unit
60 motor unit
62 servo drive circuit
100 main control unit
140 clock generation circuit
142A delay circuit
150 film thickness measurement unit
200 mist generation chamber
201A, 201B cylinder
202 pipe
203 laminar flow filter
204 collecting unit
204b opening
205 solution tank
206 ultrasonic transducer
207 drive circuit
208 reserve tank
209 pipe
210 trap
211 pedestal
212 mist transport path
214 substrate holder
215 gas introduction pipe
270 base
271A introduction port
271B exhaust port
272 spacer
274 plate
274A ejection hole
274B suction hole
275 heater
300A parallel flat plate
301A rectangular column member
c plasma
Cg, Cp dielectric
Cg1, Cg2, Cp1, Cp2, Cp3 quartz tube
CLK clock pulse
CR1, CR2, CR3, CR4 roller
Dh opening
EG, EG1, EG2, EP, EP1, EP2, EP3, EP4 electrode
EH1, EH2 encoder head part (head part)
EQ1, EQ2 mount
ES1, ES2 edge sensor
Fn1, Fn2, Fn3 fin member
FS substrate
FV1, FV2, FV3 flow regulation valve
Ka, Kb, Kc, Kd line segment
Lb, Lc interval
LQ precursor
Mgs mist gas
Nu1 circular tube part
Nu2 funnel part
PA region
Pz center plane
RL1 supply roll
RL2 collection roll
SD scale disk
Sf shaft
Sfa, Sfb, Sfc inner wall
SN, SN1, SN2, SN3, SN4 aperture
TB1, TB2, TB3 air turn bar
Tu time
Vo1, Vo2, Vo2a, Vo2b, Vo2c, Vo2d voltage
WD interval

1. A thin film manufacturing device for forming a thin film on a substrate by supplying a mist of a solution comprising a thin-film forming material to the substrate,
the device comprising:
a plasma generation unit comprising a first electrode and a second electrode disposed closer to one surface of the substrate, which generates plasma between the first electrode and the second electrode; and
a mist supply unit which passes the mist between the first electrode and the second electrode and supplies the mist to the substrate.

2. The thin film manufacturing device according to claim 1, wherein the first electrode and the second electrode are arranged substantially in parallel.

3. The thin film manufacturing device according to claim 1, wherein the first electrode and the second electrode have a part opposed at a predetermined interval, and the part has a linear shape at the narrowest interval.

4. The thin film manufacturing device according to claim 1, wherein a distance between one of the first electrode or the second electrode, which is closer to the substrate, and the substrate is longer than a distance between the first electrode and the second electrode.

5. The thin film manufacturing device according to claim 1, wherein at least one of the first electrode and the second electrode is covered with a dielectric.

6. The thin film manufacturing device according to claim 1, comprising a conveying unit that conveys the substrate comprising a resin and which is flexible to the plasma generation unit.

7. The thin film manufacturing device according to claim 6, wherein the conveying unit has a substantially arc shape comprising the plasma generation unit on an outer peripheral side.

8. The thin film manufacturing device according to claim 1, wherein the substrate is inclined with respect to a horizontal plane.

9. The thin film manufacturing device according to claim 1, comprising a power supply unit that applies a voltage to the plasma generation unit, wherein
the power supply unit applies a voltage at a frequency of 1 kHz or more and less than 6 kHz.

10. The thin film manufacturing device according to claim 9, wherein the power supply unit applies a voltage of 19 kV or more.

11. The thin film manufacturing device according to claim 9, wherein the power supply unit applies a voltage to cause the plasma generation unit to generate an electric field of 3.8×10⁶ V/m or more.

12. The thin film manufacturing device according to claim 1, wherein the solution comprises a metal salt or a metal complex of at least one or more of zinc, indium, tin, gallium, titanium, aluminum, iron, cobalt, nickel, copper, silicon, hafnium, tantalum and tungsten.

13. The thin film manufacturing device according to claim 1, wherein the solution is a dispersion liquid of metal oxide fine particles comprising at least one or more of indium, zinc, tin, and titanium.

14. A thin film manufacturing method for forming a thin film on a substrate by supplying a mist of a solution comprising a thin-film forming material to the substrate,
the method comprising:
generating plasma between a first electrode and a second electrode disposed closer to one surface of the substrate; and
passing the mist between the first electrode and the second electrode and supplying the mist to the substrate.

15. The thin film manufacturing method according to claim 14, wherein the first electrode and the second electrode are arranged substantially in parallel.

16. The thin film manufacturing method according to claim 14, wherein the first electrode and the second electrode have a part opposed at a predetermined interval, and the part has a linear shape at the narrowest interval.

17. The thin film manufacturing method according to claim 14, wherein generating the plasma comprises applying a voltage between the first electrode and the second electrode at a frequency of 1 kHz or more and less than 6 kHz.

18. The thin film manufacturing method according to claim 17, wherein generating the plasma comprises applying a voltage of 19 kV or more.

19. The thin film manufacturing method according to claim 17, wherein generating the plasma comprises applying a voltage to generate an electric field of 3.8×10⁶ V/m or more between the first electrode and the second electrode.
